(19) United States
(12) Patent Application Publication
(10) Pub. No.: US 2022/0255293 A1
(43) Pub. Date: Aug. 11, 2022

(54) SEMICONDUCTOR LASER DEVICE AND EXTERNAL RESONANCE-TYPE LASER DEVICE

(71) Applicant: PANASONIC CORPORATION, Osaka (JP)

(72) Inventors: Takashi KANO, Shiga (JP); Hiroyuki HAGINO, Osaka (JP)

(21) Appl. No.: 17/609,721

(22) PCT Filed: Feb. 12, 2020
(86) PCT No.: PCT/JP2020/005415

§ 371 Date: Nov. 8, 2021

(30) Foreign Application Priority Data
May 9, 2019 (JP) 2019-089320

(51) Int. Cl. H01S 5/024; H01S 5/22; H01S 5/40; H01S 5/343; H01S 5/30; H01S 5/026; H01S 5/14; H01S 5/0234

(52) U.S. Cl. CPC H01S 5/02469; H01S 5/2205; H01S 5/4062; H01S 5/0234; H01S 5/3063; H01S 5/026; H01S 5/143; H01S 5/34333

(57) ABSTRACT

A semiconductor laser element includes a light emission layer and a plurality of waveguides to arranged in one direction. A semiconductor laser device includes the semiconductor laser element and a first base disposed, via a first adhesion layer, on one face in the lamination direction of the semiconductor laser element. The thermal resistance of the first adhesion layer is, in the arrangement direction of the plurality of waveguides to lower on one end portion side than on the other end portion side.

### TECHNICAL FIELD

The present invention relates to a semiconductor laser device and an external resonance-type laser device each including an array-type semiconductor laser element, and is suitable for use in processing of products, for example.

The present application is a commissioned research under “Development of advanced laser processing with intelligence based on high-brightness and high-efficiency laser technologies/Development of new light-source/elemental technologies for advanced processing/Development of GaN-based high-power high-beam quality semiconductor lasers for highly-efficient laser processing” of the New Energy and Industrial Technology Development Organization for the fiscal year 2016, and is a patent application to which Article 17 of the Industrial Technology Enhancement Act is applied.

### BACKGROUND ART

In recent years, semiconductor laser devices have been used in processing of various products. In such a case, in order to enhance the processing quality, light emitted from a semiconductor laser device preferably has a high output power. PATENT LITERATURE 1 below describes a semiconductor laser device that includes: a semiconductor laser element having a plurality of stripes arrayed in a row at a predetermined interval; and a support body on which this semiconductor laser element is disposed.

As a technique for enhancing the beam quality, used is a wavelength combining method that condenses, by use of an optical system, a plurality of laser beams having wavelengths different from each other. In this wavelength combining method, since the beams can be condensed to one place, a high beam quality can be realized. As a structure capable of precisely controlling the oscillation wavelengths of individual lasers, a DFB (Distributed Feedback) laser, a DBR (Distributed Bragg Reflector) laser, an external resonator using an optical element, or the like is used. PATENT LITERATURE 2 below describes, as an example of an optical system using a wavelength combining method, an external resonance-type laser device that includes a laser array, a diffraction grating, and an output coupler implemented as a partial reflector.

### CITATION LIST

### Patent Literature

[PTL 1] Japanese Laid-Open Patent Publication No. H1-164084
[PTL 2] Japanese Patent No. 5892918

### SUMMARY OF THE INVENTION

### Problems to be Solved by the Invention

In an external resonance-type laser device in which a laser array and a diffraction grating are combined as described above, the oscillation wavelength at each waveguide of the laser array is determined by the incidence angle to the diffraction grating. Therefore, the oscillation wavelengths at the respective waveguides in the laser array vary in one direction in accordance with the positions of the waveguides. For example, the oscillation wavelength of a laser array gradually changes to a long wave, from a waveguide positioned at one end toward a waveguide at the other end. Meanwhile, among a plurality of waveguides in a laser array, the temperature of the waveguide at the center becomes highest. Therefore, the gain spectrum necessary for oscillation becomes a long wave at the waveguide at the center, and becomes a short wave at the waveguides at the ends. Such a state causes, in a waveguide, a mismatch between the gain spectrum determined by the temperature distribution and the oscillation wavelength determined by the incidence angle to the diffraction grating. This causes a problem that the light emission efficiency of laser is significantly decreased.

In view of the above problem, an object of the present invention is to provide a semiconductor laser device and an external resonance-type laser device that are capable of suppressing decrease in the light emission efficiency.

### Solution to the Problems

A first mode of the present invention relates to a semiconductor laser device. The semiconductor laser device according to the present mode includes: a semiconductor laser element including a light emission layer and a plurality of waveguides arranged in one direction; and a first base disposed, via a first adhesion layer, on one face in a lamination direction of the semiconductor laser element. A thermal resistance of the first adhesion layer is, in an arrangement direction of the plurality of waveguides, lower on one end portion side than on another end portion side.

When the semiconductor laser device is used in an external resonance-type laser device including a diffraction grating, the oscillation wavelength at each waveguide of the semiconductor laser device is determined by the configuration (e.g., the incidence angle to the diffraction grating) of the optical system. Therefore, the oscillation wavelengths at the respective waveguides vary in one direction in accordance with the positions of the waveguides. For example, the oscillation wavelength of the semiconductor laser device gradually changes to a long wave, from the waveguide on the one end portion side toward the waveguide on the other end portion side.

According to the semiconductor laser device of the present mode, the thermal resistance of the first adhesion layer is, in the arrangement direction of the plurality of waveguides, lower on the one end portion side than on the other end portion side. Accordingly, movement of heat to the first base is promoted in the vicinity of the one end portion side of the semiconductor laser element. Accordingly, the temperature on the other end portion side becomes higher than the temperature on the one end portion side. As a result, the gain spectrum of the waveguide positioned on the other end portion side becomes a longer wave than the gain spectrum of the waveguide positioned on the one end portion side. Therefore, the distribution of the gain spectra in the arrangement direction of the plurality of waveguides comes to agree with the oscillation wavelengths determined by the configuration of the optical system of the external resonance-type laser device. Accordingly, the oscillation wavelengths determined by the configuration of the optical system of the external resonance-type laser device can be caused to fall in the ranges of the gain spectra determined by the temperature distribution. Therefore, decrease in the light emission efficiency at each waveguide of the semiconductor laser device can be suppressed.

A second mode of the present invention relates to an external resonance-type laser device. The external resonance-type laser device according to the present mode includes: the semiconductor laser device according to the first mode; a diffraction grating; and a partial reflector. The diffraction grating includes diffraction grooves extending in a direction that is parallel to a direction perpendicular to the arrangement direction of the plurality of waveguides. The diffraction grating is configured to align optical axes of a plurality of laser beams emitted in accordance with the plurality of waveguides from the semiconductor laser device. The partial reflector is configured to reflect and guide to the diffraction grating a part of the plurality of laser beams of which the optical axes have been caused to overlap with each other by the diffraction grating.

According to the external resonance-type laser device of the present mode, the oscillation wavelength at each waveguide of the semiconductor laser device is determined by the incidence angle to the diffraction grating. Therefore, the oscillation wavelengths at the respective waveguides vary in one direction in accordance with the positions of the waveguides. For example, the oscillation wavelength of the semiconductor laser device gradually changes to a long wave, from the waveguide on the one end portion side toward the waveguide on the other end portion side.

According to the external resonance-type laser device of the present mode, similar to the first mode, the thermal resistance of the first adhesion layer is, in the arrangement direction of the plurality of waveguides, lower on the one end portion side than on the other end portion side. Accordingly, movement of heat to the first base is promoted in the vicinity of the one end portion side of the semiconductor laser element. Accordingly, the temperature on the other end portion side becomes higher than the temperature on the one end portion side. As a result, the gain spectrum of the waveguide positioned on the other end portion side becomes a longer wave than the gain spectrum of the waveguide positioned on the one end portion side. Therefore, the distribution of the gain spectra in the arrangement direction of the plurality of waveguides comes to agree with the oscillation wavelengths determined by the incidence angles to the diffraction grating. Accordingly, the oscillation wavelengths determined by the incidence angles to the diffraction grating can be caused to fall in the ranges of the gain spectra determined by the temperature distribution. Therefore, decrease in the light emission efficiency at each waveguide of the semiconductor laser device can be suppressed, and the efficiency of laser oscillation by the external resonance-type laser device can be enhanced.

### Advantageous Effects of the Invention

As described above, according to the present invention, a semiconductor laser device and an external resonance-type laser device that are capable of suppressing decrease in the light emission efficiency can be provided.

The effects and the significance of the present invention will be further clarified by the description of the embodiments below. However, the embodiments below are merely examples for implementing the present invention. The present invention is not limited to the embodiments below in any way.

### BRIEF DESCRIPTION OF THE DRAWINGS

FIG. 1(a) is a top view schematically showing a configuration of a semiconductor laser element according to Embodiment 1. FIG. 1(b) is a cross-sectional view schematically showing a configuration of the semiconductor laser element according to Embodiment 1.

FIGS. 2(a), 2(b) are each a cross-sectional view for describing a production method of the semiconductor laser element according to Embodiment 1.

FIGS. 3(a), 3(b) are each a cross-sectional view for describing the production method of the semiconductor laser element according to Embodiment 1.

FIGS. 4(a), 4(b) are each a cross-sectional view for describing the production method of the semiconductor laser element according to Embodiment 1.

FIGS. 5(a), 5(b) are each a cross-sectional view for describing the production method of the semiconductor laser element according to Embodiment 1.

FIG. 6 is a cross-sectional view schematically showing a configuration of a semiconductor laser device according to Embodiment 1.

FIG. 7(a) is a top view schematically showing solder members disposed on a first base according to Embodiment 1. FIG. 7(b) is a graph showing the Au composition ratio of the plurality of solder members according to Embodiment 1. FIG. 7(c) is a graph showing the Au composition ratio of the first adhesion layer after the semiconductor laser element and a first electrode have been adhered, according to Embodiment 1.

FIG. 8(a) is a top view schematically showing a solder member disposed on a second base according to Embodiment 1. FIG. 8(b) is a graph showing the Au composition ratio of a plurality of solder members according to Embodiment 1. FIG. 8(c) is a graph showing the Au composition ratio of a second adhesion layer after the semiconductor laser element and the second base have been adhered, according to Embodiment 1.

FIG. 9(a) is a graph showing a relationship between the Sn composition ratio and the thermal conductivity. FIG. 9(b) is a graph showing the thermal conductivity of the first adhesion layer according to Embodiment 1. FIG. 9(c) is a graph conceptually showing temperatures in the Y-axis direction of the semiconductor laser element according to Embodiment 1 and Comparative Example.

FIG. 10 is a top view schematically showing a basic configuration of an external resonance-type laser device according to Embodiment 1.

FIG. 11(a) is a schematic diagram showing a gain spectrum at each waveguide of a semiconductor laser element and an oscillation wavelength by an external resonance-type laser device according to Comparative Example. FIG. 11(b) is a schematic diagram showing a gain spectrum at each waveguide of the semiconductor laser element and an oscillation wavelength by the external resonance-type laser device according to Embodiment 1.

FIG. 12 is a cross-sectional view schematically showing a configuration of a semiconductor laser device according to Embodiment 2.

FIG. 13(a) is a top view schematically showing solder members disposed on a first base according to Embodiment 2. FIG. 13(b) is a graph showing the Au composition ratio of the plurality of solder members according to Embodiment 2. FIG. 13(c) is a graph showing the Au composition ratio of a first adhesion layer after a semiconductor laser element and a first electrode have been adhered, according to Embodiment 2.

FIG. 14(a) is a graph showing the thermal conductivity of the first adhesion layer according to Embodiment 2. FIG. 14(b) is a graph conceptually showing temperatures in the Y-axis direction of the semiconductor laser element according to Embodiment 2 and Comparative Example. FIG. 14(c) is a schematic diagram showing a gain spectrum of an oscillation wavelength at each waveguide of the semiconductor laser element and an oscillation wavelength by the external resonance-type laser device according to Embodiment 2.

FIG. 15 is a cross-sectional view schematically showing a configuration of a semiconductor laser device according to Embodiment 3.

FIG. 16(a) is a perspective view schematically showing configurations of protrusion parts according to Embodiment 3. FIG. 16(b) is a perspective view schematically showing a configuration of a partition member according to a modification of Embodiment 3.

FIG. 17 is a cross-sectional view schematically showing a configuration of a semiconductor laser device according to Embodiment 4.

FIGS. 18(a), 18(b) are each a graph showing the thermal conductivity of a second adhesion layer and a first adhesion layer according to another modification.

FIGS. 19(a), 19(b) are each a graph showing the thermal conductivity of a second adhesion layer and a first adhesion layer according to another modification.

FIGS. 20(a), 20(b) are each a top view schematically showing a configuration of an external resonance-type laser device according to another modification.

It should be noted that the drawings are solely for description and do not limit the scope of the present invention by any degree.

### BEST MODE FOR CARRYING OUT THE INVENTION

Hereinafter, embodiments of the present invention will be described with reference to the drawings. For convenience, each drawing is provided with, X, Y, and Z axes orthogonal to each other. The X-axis direction is the propagation direction of light at a waveguide, and the Y-axis direction is the width direction (arrangement direction of waveguides) of the waveguide. The Z-axis direction is the lamination direction of layers that form a semiconductor laser element.

In the embodiments below, the thermal resistance of a first adhesion layer is, in the arrangement direction of a plurality of waveguides, lower on one end portion side than on the other end portion side. In order to realize such a thermal resistance distribution, in the embodiments below, the thermal conductivity of the first adhesion layer is, in the arrangement direction of the plurality of waveguides, higher on the one end portion side than on the other end portion side. Similarly, in the embodiments below, the thermal resistance of a second adhesion layer is, in the arrangement direction of the plurality of waveguides, lower on the one end portion side than on the other end portion side. In order to realize such a thermal resistance distribution, in the embodiments below, the thermal conductivity of the second adhesion layer is, in the arrangement direction of the plurality of waveguides, higher on the one end portion side than on the other end portion side.

### Embodiment 1

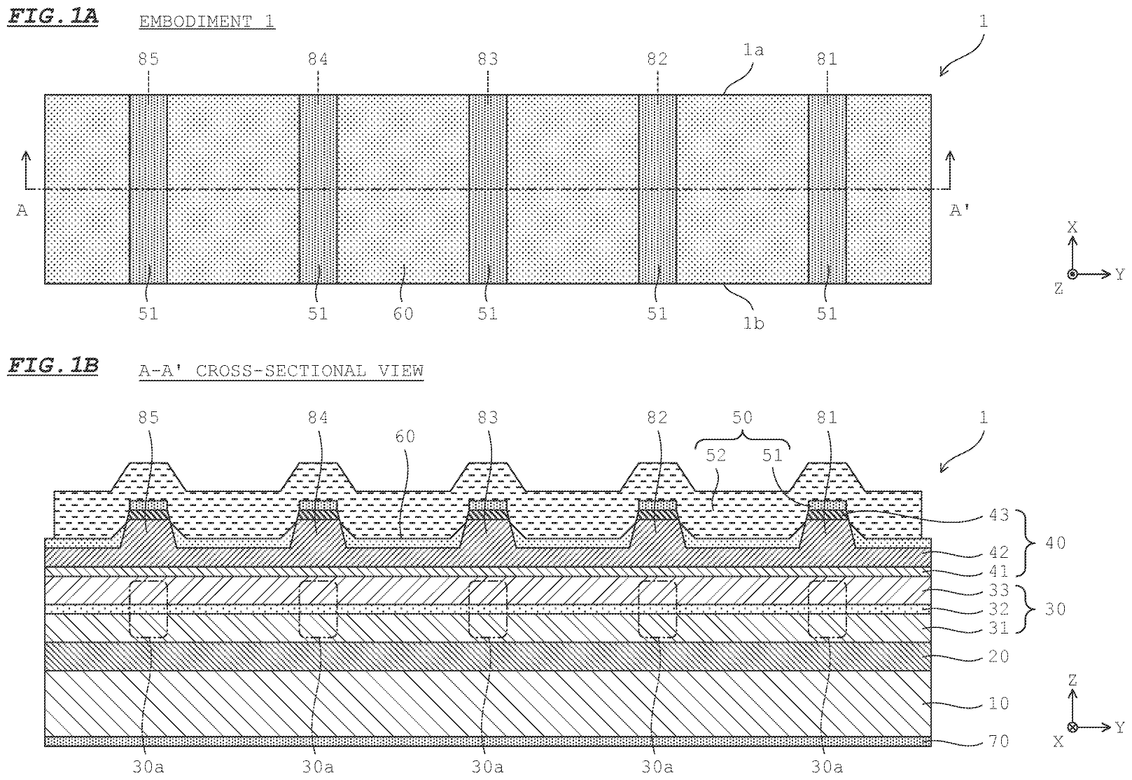

FIG. 1(a) is a top view schematically showing a configuration of a semiconductor laser element 1, and FIG. 1(b) is a cross-sectional view schematically showing a configuration of the semiconductor laser element 1. In FIG. 1(a), for convenience, a pad electrode 52 is not shown. FIG. 1(b) is a cross-sectional view in the X-axis positive direction of the semiconductor laser element 1 cut along A-A′ in FIG. 1(a).

As shown in FIG. 1(a), the semiconductor laser element 1 is provided with five waveguides 81 to 85 extending in the X-axis direction. The five waveguides 81 to 85 have an action of guiding light into the X-axis direction and of restricting, in the Y-axis direction, advancement of light to the outside of these waveguides.

An end face 1a is the end face on the emission side of the semiconductor laser element 1, and an end face 1b is the end face on the reflection side of the semiconductor laser element 1. Light from the end face 1a side toward the end face 1b is amplified while advancing in the X-axis negative direction in the waveguides 81 to 85, and is reflected at the end face 1b. Light from the end face 1b side toward the end face 1a is amplified while advancing in the X-axis positive direction in the waveguides 81 to 85, passes through the end face 1a, and is emitted, as emission light, in the X-axis positive direction from the end face 1a. In this manner, light generated in the semiconductor laser element 1 is amplified between the end face 1a and the end face 1b, to be emitted from the end face 1a.

However, in the case of an external resonance-type laser device described later, light amplification is performed through reflection using an output coupler. Therefore, it is preferable to adopt a configuration in which: the reflectance at the end face 1a is substantially zero; and light amplification in the semiconductor laser element 1 is not performed.

As shown in FIG. 1(b), the semiconductor laser element 1 includes a substrate 10, a first semiconductor layer 20, a light emission layer 30, a second semiconductor layer 40, an electrode part 50, a dielectric layer 60, and an n-side electrode 70.

The substrate 10 is a GaN substrate, for example. In the present embodiment, the substrate 10 is an n-type hexagonal GaN substrate of which the main face is a (0001) plane.

The substrate 10 is formed on the first semiconductor layer 20. The first semiconductor layer 20 is, for example, an n-side clad layer formed of an Si-doped n-type AlGaN.

The light emission layer 30 is formed on the first semiconductor layer 20. The light emission layer 30 is implemented as a nitride semiconductor. For example, the light emission layer 30 has a structure in which an n-side light guide layer 31 composed of n-GaN and an undoped InGaN layer, an active layer 32 formed as an InGaN quantum well layer, and a p-side light guide layer 33 composed of an undoped InGaN layer and Mg-doped p-GaN are laminated. Light emission regions 30a are respectively present, in the light emission layer 30, in the vicinities of positions corresponding to the five waveguides 81 to 85, and are regions where most of light emitted from the semiconductor laser element 1 is generated and propagates.

The second semiconductor layer 40 is formed on the light emission layer 30. For example, the second semiconductor layer 40 has a structure in which an electron barrier layer 41 formed of AlGaN, a p-side clad layer 42 formed as an Mg-doped p-type AlGaN layer, and a p-side contact layer 43 formed of a p-type GaN similarly doped with Mg are laminated. The p-side contact layer 43 is formed as the uppermost layer of the five waveguides 81 to 85. The second semiconductor layer 40 includes, on the upper face thereof, five protrusion parts (projections in a stripe shape) extending in the X-axis direction. The five protrusion parts formed at the second semiconductor layer 40 form the five waveguides 81 to 85. Due to the five waveguides 81 to 85, light advances along the X-axis direction in the five light emission regions 30a corresponding to the five waveguides 81 to 85.

The electrode part 50 is formed on the second semiconductor layer 40. The electrode part 50 includes: p-side electrodes 51 for supplying current; and a pad electrode 52 formed on the p-side electrodes 51. Each p-side electrode 51 is formed on the p-side contact layer 43, and extends in the X-axis direction along the corresponding waveguide 81 to 85, as shown in FIG. 1(a). The p-side electrode 51 is an ohmic electrode that is in ohmic contact with the p-side contact layer 43. For example, the p-side electrode 51 is formed by using a metal material such as Pd, Pt, and Ni. In the present embodiment, the p-side electrode 51 has a two-layer structure of Pd/Pt. The pad electrode 52 is disposed above the p-side electrodes 51 and the dielectric layer 60, and covers a substantially entire region of the upper face of the semiconductor laser element 1. For example, the pad electrode 52 is formed by using a metal material such as Ti, Ni, Pt, and Au. In the present embodiment, the pad electrode 52 has a three-layer structure of Ti/Pt/Au.

The dielectric layer 60 is an insulation film formed on the outer sides of the five waveguides 81 to 85, in order to confine the light to the light emission regions 30a. In the present embodiment, the dielectric layer 60 is continuously formed, in the peripheries of the five waveguides 81 to 85, over the side faces of the p-side contact layer 43, the side faces of the protruding portions of the p-side clad layer 42, and the upper faces, in the peripheries of the protruding portions, of the A-side clad layer 42. In the present embodiment, the dielectric layer 60 is formed of SiO₂.

The n-side electrode 70 is formed at the lower face of the substrate 10, and is an ohmic electrode in ohmic contact with the substrate 10. For example, the n-side electrode 70 is a lamination film composed of Ti/Pt/Au.

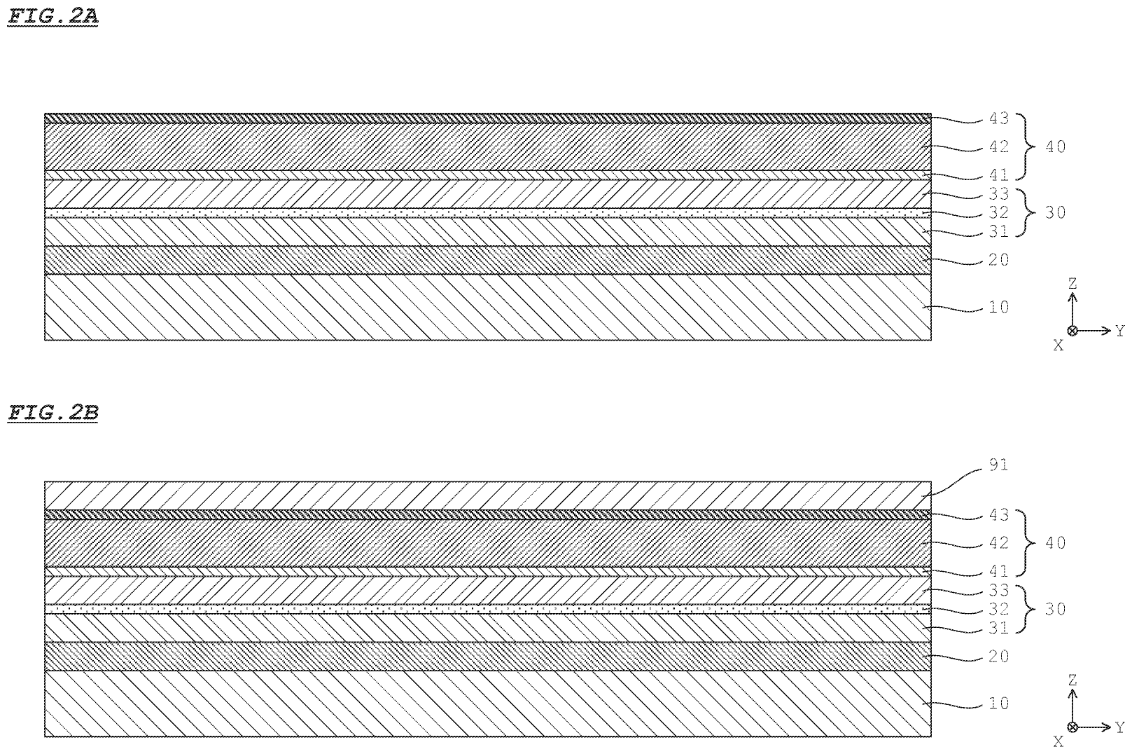

Next, a production method of the semiconductor laser element 1 is described with reference to FIG. 2(a) to FIG. 5(b). FIG. 2(a) to FIG. 5(b) are cross-sectional views similar to that in FIG. 1(b).

As shown in FIG. 2(a), the first semiconductor layer 20, the light emission layer 30, and the second semiconductor layer 40 are sequentially formed through Metalorganic Chemical Vapor Deposition (MOCVD method) on the substrate 10, which is an n-type hexagonal GaN substrate of which the main face is a (0001) plane.

Specifically, an n-side clad layer of an n-type AlGaN is grown by 3 μm as the first semiconductor layer 20, on the substrate 10 having a thickness of 400 μm. Subsequently, the n-side light guide layer 31 of n-GaN is grown by 0.1 μm. Subsequently, the active layer 32 composed of three cycles of a barrier layer of InGaN and an InGaN quantum well layer is grown. Subsequently, the p-side light guide layer 33 of p-GaN is grown by 0.1 μm.

Subsequently, the electron barrier layer 41 of AlGaN is grown by 10 nm. Subsequently, the p-side clad layer 42 is grown as a 0.48 μm-thick strained superlattice, by repeating 160 cycles of a 1.5 nm-thick p-AlGaN layer and a 1.5 nm-thick GaN layer. Subsequently, the p-side contact layer 43 of p-GaN is grown by 0.05 μm. Here, in each layer, for organometal raw materials including Ga, Al, and In, trimethylgallium (TMG), trimethyl ammonium (TMA), and trimethylindium (TMI) are respectively used, for example. For a nitrogen raw material, ammonia (NH₃) is used.

Next, as shown in FIG. 2(b), a protection film 91 is formed on the second semiconductor layer 40. Specifically, as the protection film 91, a 300 nm silicon oxide film (SiO₂) is formed on the p-side contact layer 43 by a plasma CVD (Chemical Vapor Deposition) method using silane (SiH₄).

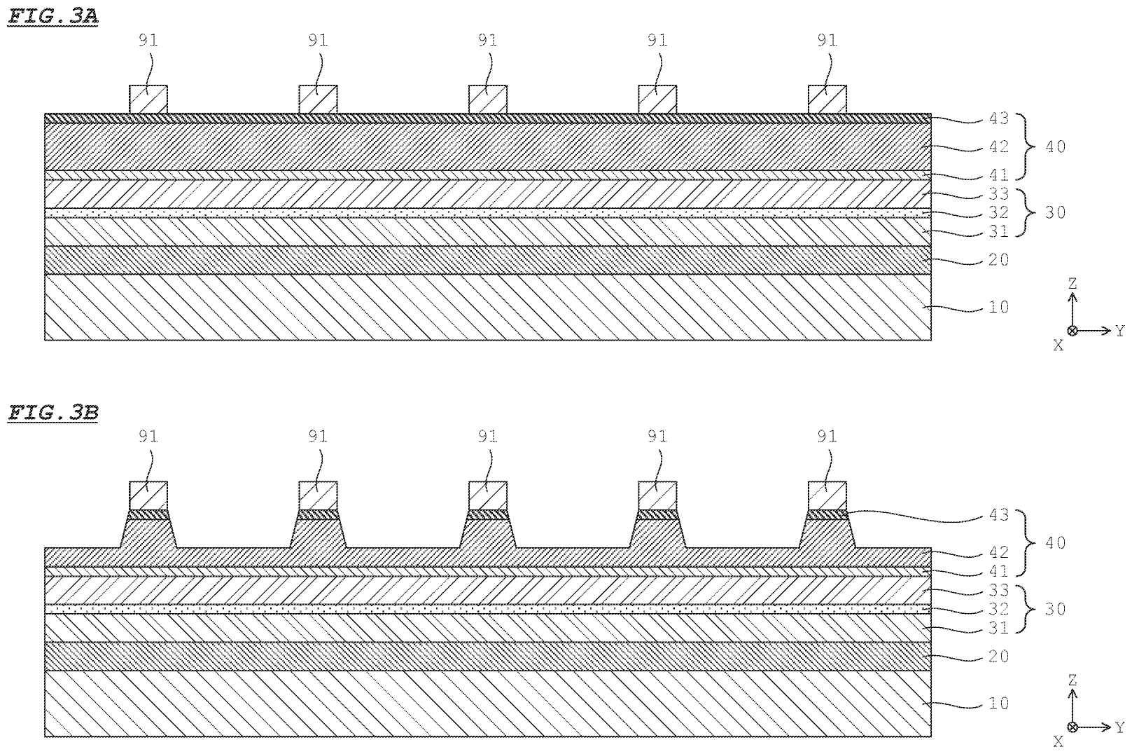

Next, as shown in FIG. 3(a), the protection film 91 is selectively removed by using a photolithography method and an etching method such that the protection film 91 remains in belt-like shapes. As the etching method, for example, dry etching by reactive ion etching (RIE) using a fluorine-based gas such as CF₄, or wet etching using hydrofluoric acid (HF) diluted at about 1:10, can be used.

Next, as shown in FIG. 3(b), the p-side contact layer 43 and the p-side clad layer 42 are etched by using, as a mask, the protection film 91 formed in the belt-like shapes, whereby five protrusion parts (projections in a stripe shape, ridge stripe parts) are formed in the second semiconductor layer 40. For etching of the p-side contact layer 43 and the p-side clad layer 42, dry etching by an RIE method using a chlorine-based gas such as Cl₂ can be used.

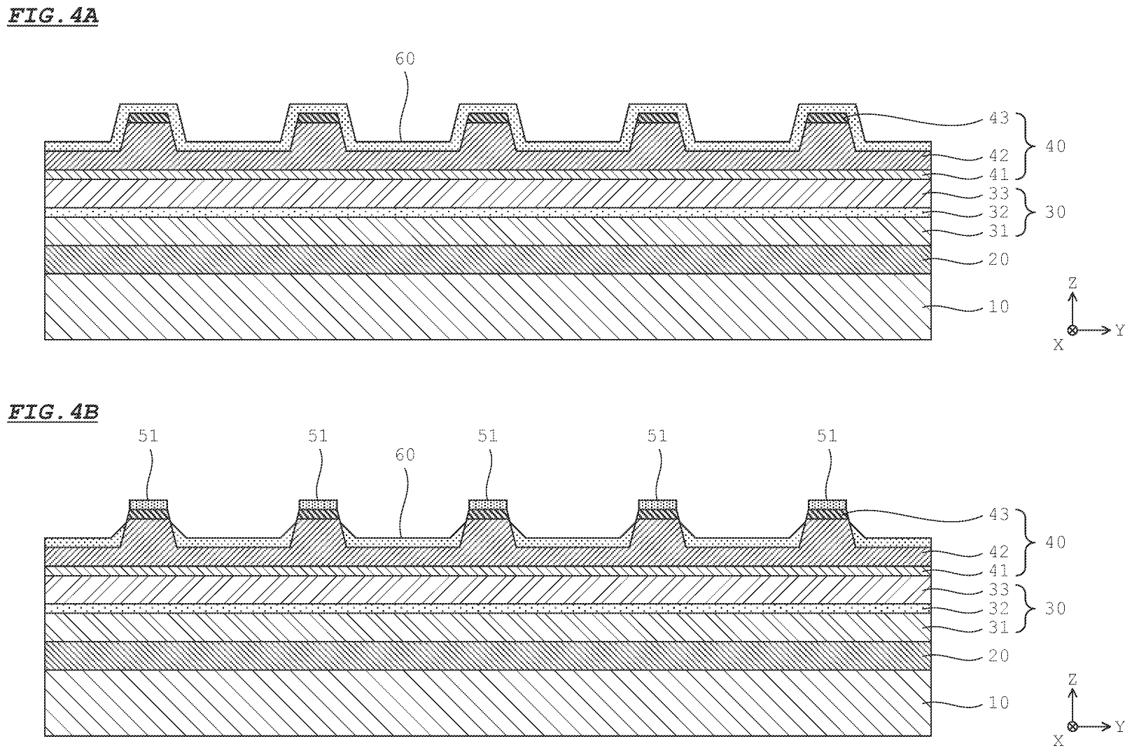

Next, as shown in FIG. 4(a), the protection film 91 in the belt-like shapes is removed by wet etching using hydrofluoric acid or the like, and then, the dielectric layer 60 is formed so as to cover the p-side contact layer 43 and the p-side clad layer 42. As the dielectric layer 60, a 300 nm silicon oxide film (SiO₂) is formed by a plasma CVD method using silane (SiH₄), for example.

Next, as shown in FIG. 4(b), only the dielectric layer 60 on the protrusion parts of the second semiconductor layer 40 is removed by a photolithography method and wet etching using hydrofluoric acid, to expose the upper faces of the p-side contact layer 43. Then, the p-side electrodes 51 each composed of Pd/Pt are formed only on the protrusion parts of the second semiconductor layer 40, by using a vacuum evaporation method and a lift-off method. Specifically, each p-side electrode 51 is formed on the p-side contact layer 43 exposed from the dielectric layer 60.

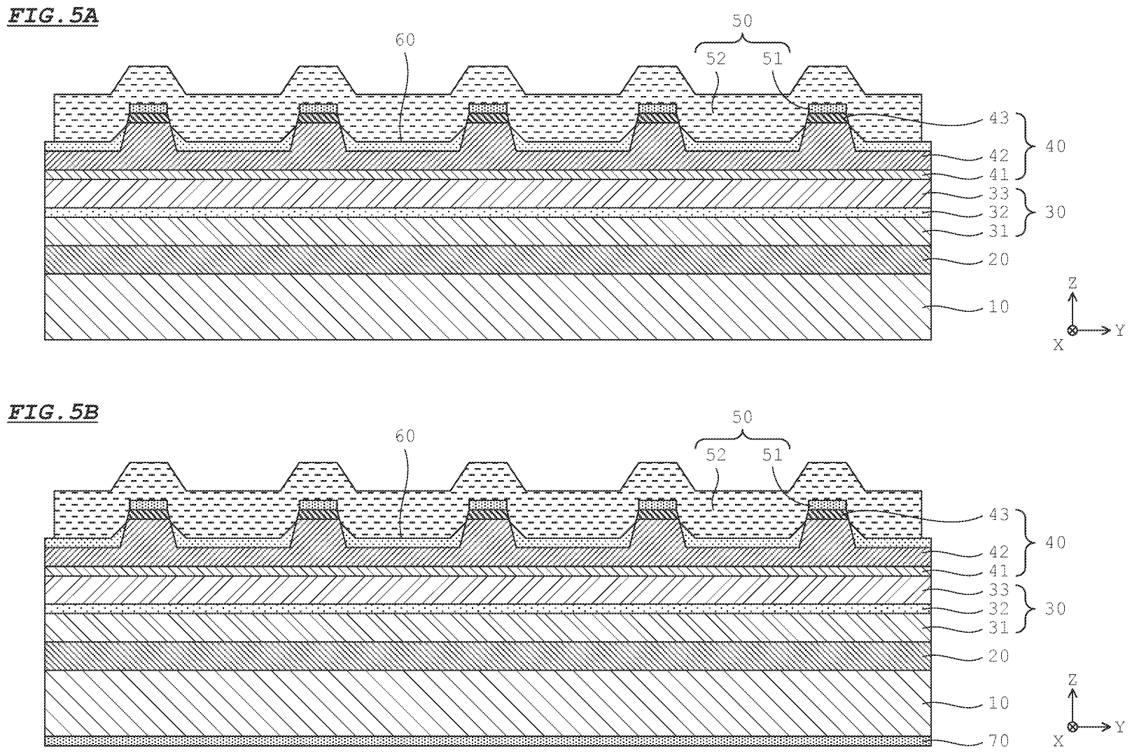

Next, as shown in FIG. 5(a), the pad electrode 52 is formed so as to cover the p-side electrodes 51 and the dielectric layer 60. Specifically, a resist is patterned by a photolithography method or the like on portions other than the portions where the pad electrode 52 is to be formed, and the pad electrode 52 composed of Ti/Pt/Au is formed on the entire face above the substrate 10 by a vacuum evaporation method or the like. Then, the electrode of unnecessary portions is removed by using a lift-off method. Accordingly, the pad electrode 52 that has a predetermined shape can be formed on the p-side electrodes 51 and the dielectric layer 60. In this manner, the electrode part 50 composed of the p-side electrodes 51 and the pad electrode 52 is formed.

Next, the lower face of the substrate 10 having a thickness of 400 μm is polished so as to have a thickness of 80 μm. Then, as shown in FIG. 5(b), the n-side electrode 70 is formed at the lower face of the substrate 10. Specifically, the n-side electrode 70 composed of Ti/Pt/Au is formed on the rear face of the substrate 10 by a vacuum evaporation method or the like, and patterning is performed by using a photolithography method and an etching method, whereby the n-side electrode 70 that has a predetermined shape is formed.

Then, the end faces 1a, 1b are formed through cleavage, and end face coat films such as dielectric multilayer films are respectively formed at the end faces 1a, 1b. The reflectance of the end face coat film formed at the end face 1a is set to be substantially 0%, and the reflectance of the end face coat film formed at the end face 1b is set to be substantially 100%. In this manner, the semiconductor laser element 1 shown in FIGS. 1(a), 1(b) is completed.

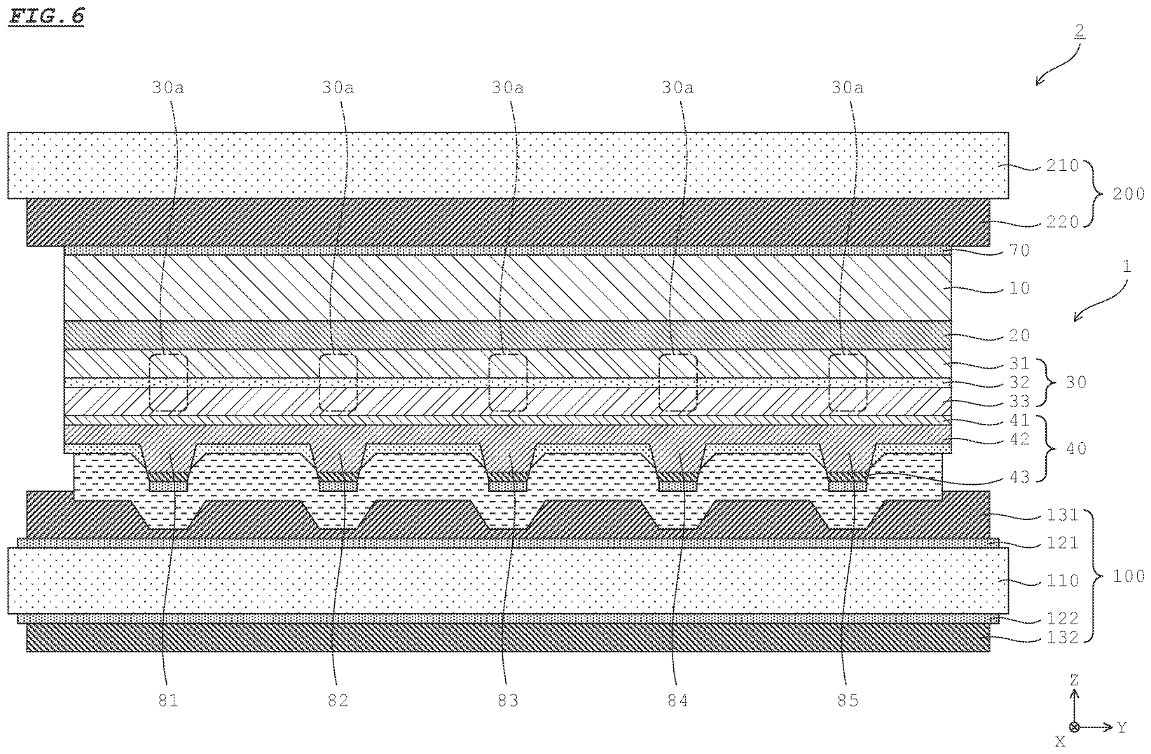

FIG. 6 is a cross-sectional view schematically showing a configuration of a semiconductor laser device 2. In FIG. 6, the upper face (the p-side face) of the semiconductor laser element 1 shown in FIG. 1(b) is directed downward (the Z-axis negative direction).

The semiconductor laser device 2 includes the semiconductor laser element 1 and two submounts 100, 200.

The submount 100 includes a first base 110, a first electrode 121, an electrode 122, a first adhesion layer 131, and an adhesion layer 132.

The first base 110 is formed of a material that has a thermal conductivity equivalent to or greater than that of the semiconductor laser element 1, such as, for example, a ceramic such as aluminum nitride (AlN) or silicon carbide (SiC), diamond (C) formed by CVD, a metal elemental substance such as Cu or Al, or an alloy such as CuW.

The first electrode 121 is formed through vapor deposition on the face, of the first base 110, that faces the semiconductor laser element 1. The electrode 122 is formed through vapor deposition on the face, of the first base 110, on the side opposite to the face on which the first electrode 121 is formed. For example, the first electrode 121 and the electrode 122 are each a lamination film composed of metals Ti (0.1 μm), Pt (0.2 μm), and Au (0.2 μm). When the first base 110 is electrically conductive and adhesion between the first base 110 and the first adhesion layer 131 is good, the first electrode 121 may be omitted.

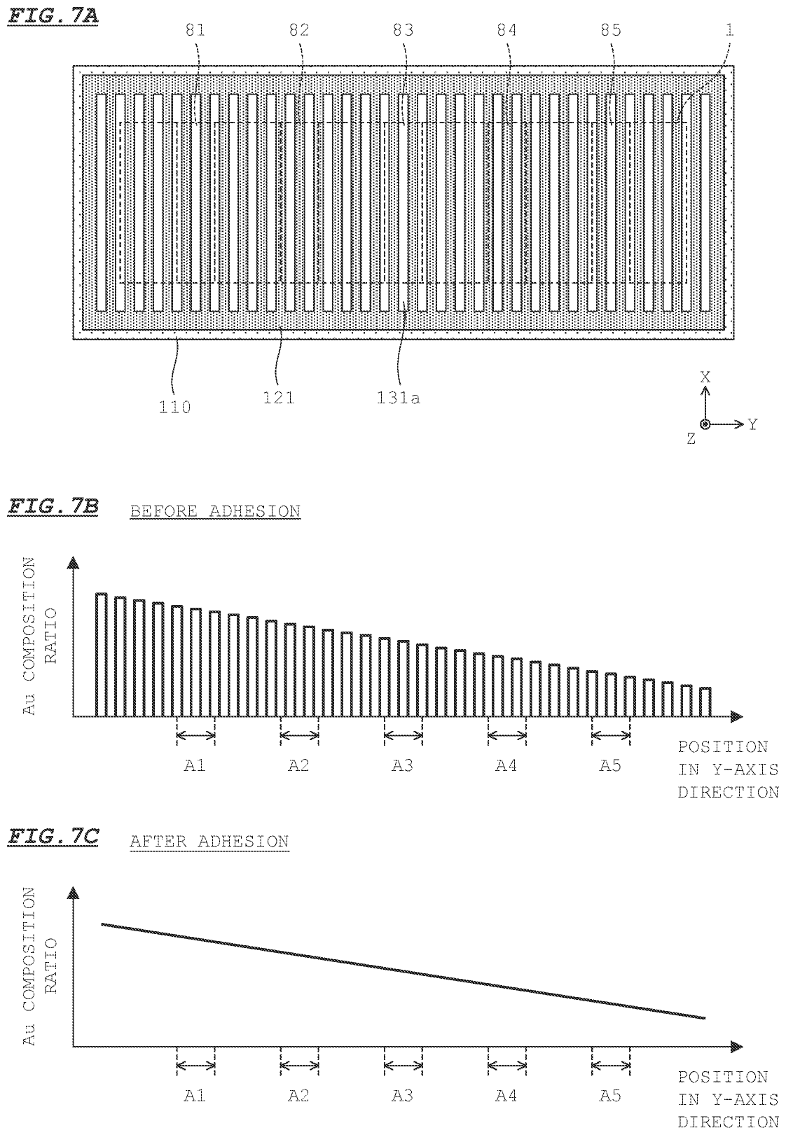

The first adhesion layer 131 is formed on the first electrode 121, and the adhesion layer 132 is formed on the electrode 122. For example, the first adhesion layer 131 is a eutectic solder (6 μm) formed of a gold tin alloy in which, with respect to a composition comprising Au (80%) and Sn (20%), the Au composition ratio varies in accordance with the position in the Y-axis direction. The Au composition ratio of the first adhesion layer 131 will be described later with reference to FIG. 7(c). The adhesion layer 132 is a eutectic solder (6 μm) formed of a gold tin alloy in which, with respect to a composition comprising Au (80%) and Sn (20%), the Au composition ratio is constant regardless of the position in the Y-axis direction.

The semiconductor laser element 1 is mounted in a junction down manner in the semiconductor laser device 2 via the first base 110. That is, the p-side face (the face on the side of the protrusion parts formed in the second semiconductor layer 40) of the semiconductor laser element 1 is disposed in the semiconductor laser device 2 via the first base 110. Specifically, the pad electrode 52 of the semiconductor laser element 1 is disposed, via the first adhesion layer 131, on the first electrode 121 formed on the first base 110, and the electrode 122 formed on the first base 110 is disposed in the semiconductor laser device 2 via the adhesion layer 132.

The submount 200 includes a second base 210 and a second adhesion layer 220.

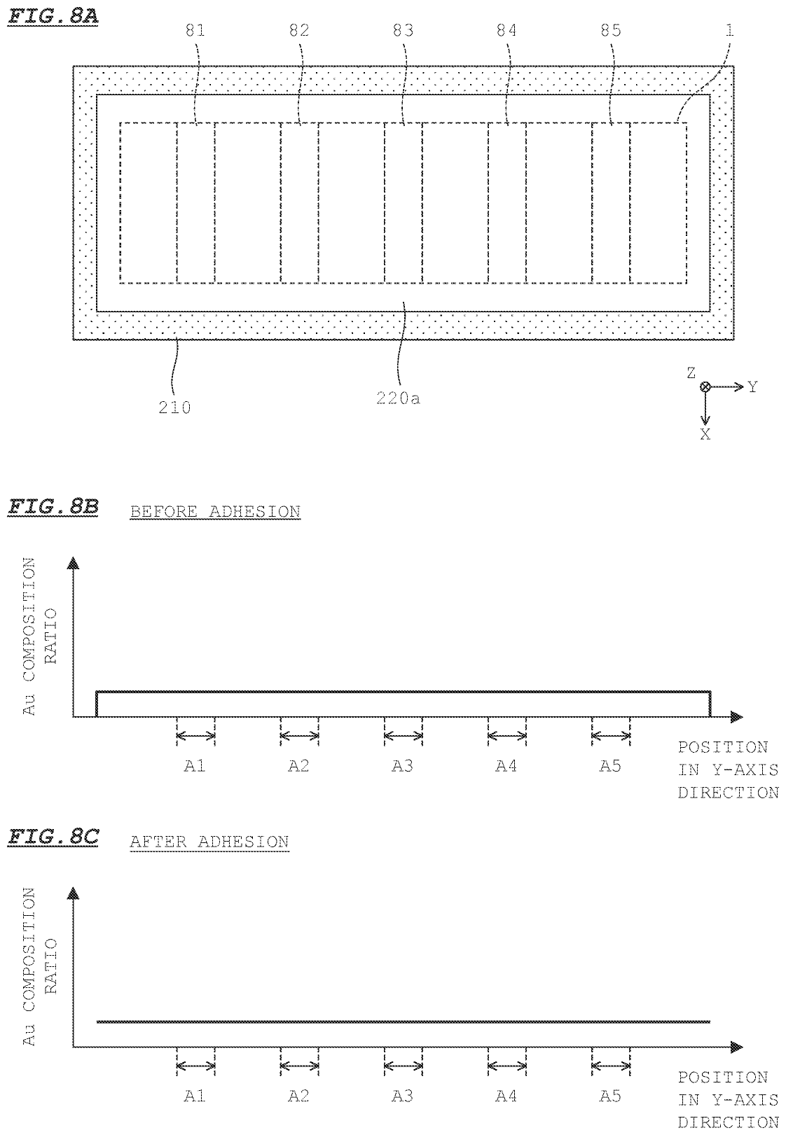

The second base 210 is formed of a material similar to that of the first base 110. The second adhesion layer 220 is formed on the face, of the second base 210, that faces the semiconductor laser element 1. The second adhesion layer 220 is a eutectic solder (6 μm) formed of a gold tin alloy in which, with respect to a composition comprising Au (80%) and Sn (20%), the Au composition ratio is constant regardless of the position in the Y-axis direction. The Au composition ratio of the second adhesion layer 220 will be described later with reference to FIG. 8(c). The n-side face (the face on the substrate 10 side) of the semiconductor laser element 1 is disposed on the second base 210 via the second adhesion layer 220.

Next, with reference to FIGS. 7(a) to 7(c), disposition of the first adhesion layer 131 and the Au composition ratio in the Y-axis direction of the first adhesion layer 131 are described.

FIG. 7(a) is a top view schematically showing solder members 131a disposed on the first base 110. FIG. 7(a) is a plan view obtained when the first base 110 and the first electrode 121 formed on the first base 110 are viewed in the Z-axis negative direction. In FIG. 7(a), for convenience, the position of the semiconductor laser element 1 and the positions of the five waveguides 81 to 85 viewed in the Z-axis direction are indicated by broken lines.

When the semiconductor laser element 1 is to be adhered to the first electrode 121 on the first base 110, a plurality of solder members 131a are disposed on the first electrode 121 as shown in FIG. 7(a). In FIG. 7(a), 33 solder members 131a are arranged in the Y-axis direction. Each solder member 131a has a width, in the Y-axis direction, that is smaller than that of each waveguide 81 to 85, and has a length, in the X-axis direction, that is greater than that of the semiconductor laser element 1. After the plurality of solder members 131a are disposed as shown in FIG. 7(a), all of the solder members 131a are melted by heat, and then, the semiconductor laser element 1 is disposed on the solder members 131a. Accordingly, the semiconductor laser element 1 and the first electrode 121 are adhered to each other by means of the solder members 131a, and the plurality of solder members 131a are connected to each other in the y-axis direction, thereby becoming the first adhesion layer 131.

FIG. 7(b) is a graph showing the Au composition ratio of the plurality of solder members 131a arranged in the Y-axis direction. In FIG. 7(b), the horizontal axis represents the position in the Y-axis direction, and the vertical axis represents the Au composition ratio. Five ranges λ1 to λ5 in the Y-axis direction in FIG. 7(b) indicate the positions of the five waveguides 81 to 85, respectively.

As shown in FIG. 7(b), the Au composition ratios of solder members 131a adjacent to each other are different from each other, but the Au composition ratio in a single solder member 131a is constant. The Au composition ratios of the 33 solder members 131a are different in accordance with the positions in the Y-axis direction. Specifically, the Au composition ratios of the plurality of solder members 131a are set such that the Au composition ratio is gradually increased from the end on the Y-axis positive side toward the end on the Y-axis negative side.

FIG. 7(c) is a graph showing the Au composition ratio of the first adhesion layer 131 after the semiconductor laser element 1 and the first electrode 121 have been adhered.

When the Au composition ratios of the plurality of solder members 131a have been set as shown in FIG. 7(b), and these solder member 131a have been melted by heat, thereby adhering the semiconductor laser element 1 and the first electrode 121 to each other, the formed first adhesion layer 131 has an Au composition ratio as shown in FIG. 7(c). In FIG. 7(c), the Au composition ratio of the first adhesion layer 131 is increased, in the arrangement direction (the Y-axis direction) of the plurality of waveguides 81 to 85, from the Y-axis positive side toward the Y-axis negative side.

In actuality, in the Au composition ratio of the first adhesion layer 131, a flat region may occur, corresponding to the position of each solder member 131a. In accordance with increase in the number of solder members 131a, the flat region is narrowed, whereby the distribution of the Au composition ratio of the first adhesion layer 131 becomes close to the smooth distribution as shown in FIG. 7(c). When the gap between the solder members 131a is reduced, these solder members 131a are mixed with each other, during melting of the solder members 131a, at the boundary between the solder members 131a adjacent to each other. Accordingly, the Au composition ratio of the first adhesion layer 131 at each boundary gently changes. As a result, the distribution of the Au composition ratio of the first adhesion layer 131 becomes close to the smooth distribution as shown in FIG. 7(c).

Next, with reference to FIGS. 8(a), 8(b), disposition of the second adhesion layer 220 and the Au composition ratio in the Y-axis direction of the second adhesion layer 220 are described.

FIG. 8(a) is a top view schematically showing the second adhesion layer 220 disposed on the second base 210. FIG. 8(a) is a plan view obtained when the second base 210 is viewed in the Z-axis positive direction. In FIG. 8(a), for convenience, the position of the semiconductor laser element 1 and the positions of the five waveguides 81 to 85 viewed in the Z-axis direction are indicated by broken lines.

When the semiconductor laser element 1 is to be disposed on the second base 210, a single solder member 220a is disposed on the second base 210 as shown in FIG. 8(a). The outer diameter of the solder member 220a is greater than the outer diameter of the semiconductor laser element 1. After the solder member 220a is disposed as shown in FIG. 8(a), the solder member 220a is melted by heat, thereby adhering the semiconductor laser element 1 onto the solder member 220a. Accordingly, the semiconductor laser element 1 and the second base 210 are adhered to each other by means of the solder member 220a, and the solder member 220a becomes the second adhesion layer 220.

FIG. 8(b) is a graph showing the Au composition ratio of the solder member 220a. In FIG. 8(b), the horizontal axis represents the position in the Y-axis direction, and the vertical axis represents the Au composition ratio. Five ranges λ1 to λ5 in the Y-axis direction in FIG. 8(b) indicate the positions of the five waveguides 81 to 85, respectively.

As shown in FIG. 8(b), the Au composition ratio of the solder member 220a is constant regardless of the position in the Y-axis direction. When the Au composition ratio of the solder member 220a is set as shown in FIG. 8(b), and the solder member 220a is melted by heat, thereby adhering the semiconductor laser element 1 and the second base 210 to each other, the Au composition ratio of the formed second adhesion layer 220 becomes constant as shown in FIG. 8(c).

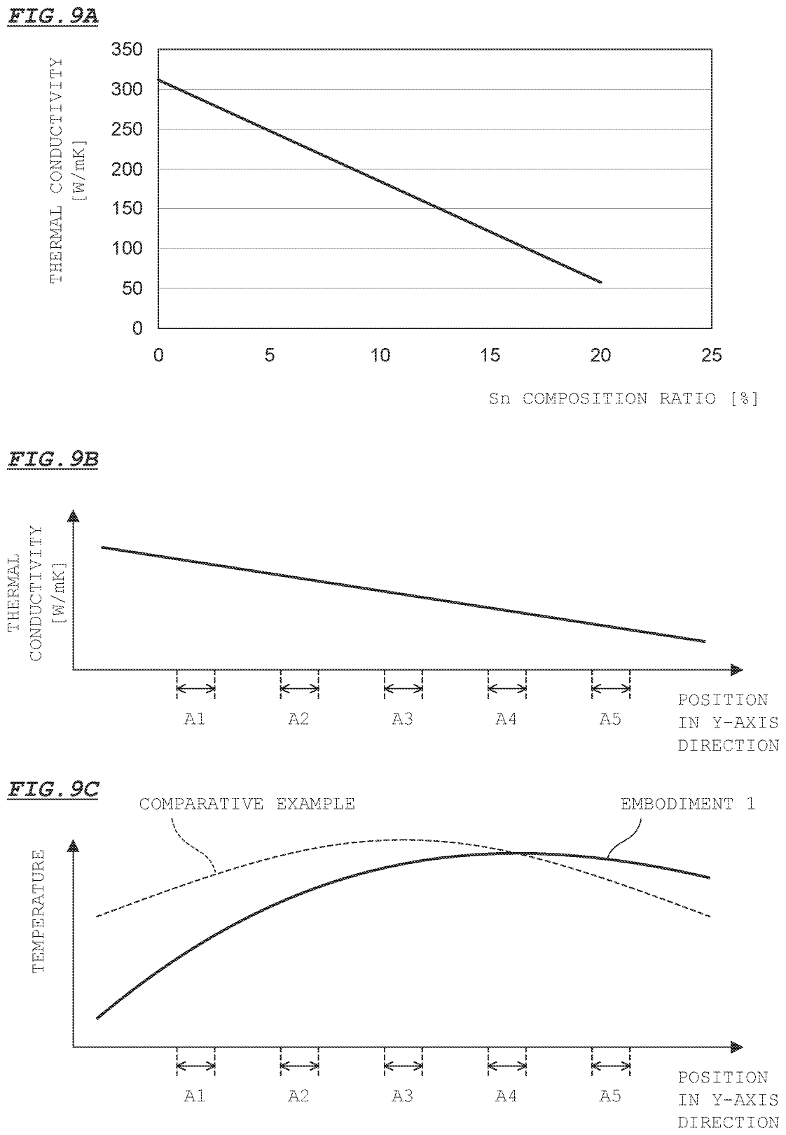

FIG. 9(a) is a graph showing a relationship between the Sn composition ratio and the thermal conductivity. The graph in FIG. 9(a) has been created by the inventors on the basis of “Physical property value—equilibrium diagram|Mitsubishi Materials Corporation Advanced Products Company Electronic Materials & Components Division” (http://www.mmc.co.jp/adv/ele/ja/products/assembly/ausn-specia103.html).

As shown in FIG. 9(a), it is seen that, when the Au composition ratio is increased and the Sn composition ratio is decreased, the thermal conductivity is increased.

Here, conventionally, the material of the adhesion layer used for adhering the semiconductor laser element 1 to a submount has been a gold tin alloy (Au0.8Sn0.2) composed of a composition comprising Au (80%) and Sn (20%). The thermal conductivity of the adhesion layer in this case is about 57 W/m·K as shown in the graph in FIG. 9(a). Since the semiconductor laser element 1 is substantially formed of GaN, the thermal conductivity of the semiconductor laser element 1 is about 200 W/m·K. Thus, in a case where an adhesion layer having a thermal conductivity that is much lower than that of the semiconductor laser element 1 is used, even if the first base 110 and the second base 210 are each formed of a material having a high thermal conductivity, heat is not smoothly conducted from the semiconductor laser element 1 to the first base 110 and the second base 210, and heat is retained in the vicinity of the center of the light emission layer 30 in particular. As a result, in the semiconductor laser element 1, the temperature at the center in the Y-axis direction becomes high, and the temperature on the outer sides in the Y-axis direction becomes low.

In contrast to this, in the case of Embodiment 1, in the semiconductor laser element 1, the temperature on the Y-axis negative side is caused to be lower than the temperature on the Y-axis positive side. Specifically, as for the first adhesion layer 131, with respect to the conventional Au composition ratio (80%), the Au composition ratio in the vicinity of the Y-axis negative side of the first adhesion layer 131 is set so as to have a higher value than the conventional value. For example, in the graph in FIG. 7(c), the Au composition ratio of the first adhesion layer 131 is set such that the Au composition ratio in the vicinity of the Y-axis positive side of the first adhesion layer 131 is not higher than the conventional value 80% and the Au composition ratio in the vicinity of the Y-axis negative side of the first adhesion layer 131 is about 95%. Meanwhile, the Au composition ratio of the second adhesion layer 220 is set to about the conventional value 80%. When the Au composition ratio of the first adhesion layer 131 is set in this manner, the heat, in the light emission layer 30, retained in the vicinity of the Y-axis negative side is more easily and smoothly conducted to the first base 110 via the first adhesion layer 131, than that in the vicinity of the Y-axis positive side.

FIG. 9(b) is a graph showing the thermal conductivity of the first adhesion layer 131.

As shown in FIG. 9(a), the thermal conductivity is increased in accordance with increase in the Au composition ratio. Therefore, when the Au composition ratio of the first adhesion layer 131 is set as shown in FIG. 7(c), the thermal conductivity of the first adhesion layer 131 is set so as to be increased from the Y-axis positive side toward the Y-axis negative side as shown in FIG. 9(b). Meanwhile, the Au composition ratio of the second adhesion layer 220 is constant as shown in FIG. 8(c), and thus, the thermal conductivity of the second adhesion layer 220 is constant regardless of the position in the Y-axis direction.

FIG. 9(c) conceptually shows temperatures in the Y-axis direction of the semiconductor laser element 1 according to Embodiment 1 and Comparative Example.

Here, Comparative Example in which the Au composition ratio of the first adhesion layer 131 is constant regardless of the position in the Y-axis direction, similar to the second adhesion layer 220, is considered. In this Comparative Example, in both of the first adhesion layer 131 leading to the first base 110 and the second adhesion layer 220 leading to the second base 210, the thermal conductivity is constant regardless of the position in the Y-axis direction. Therefore, heat in the vicinity of the center of the semiconductor laser element 1 in the arrangement direction (the Y-axis direction) of the five waveguides 81 to 85 is easily retained in the semiconductor laser element 1. Thus, in the case of Comparative Example, as shown in the graph in FIG. 9(c), due to mutual interference of heat generated in the five waveguides 81 to 85, the temperature in the vicinity of (the vicinity of the light emission region 30a that corresponds to the waveguide 83) the center of the light emission layer 30 becomes high.

In contrast to this, in the case of Embodiment 1, in the first adhesion layer 131 leading to the first base 110, the thermal conductivity in the vicinity of the Y-axis negative side is increased as shown in FIG. 9(b). Therefore, the heat in the vicinity of the Y-axis negative side of the semiconductor laser element 1 in the arrangement direction (the Y-axis direction) of the five waveguides 81 to 85 is more smoothly conducted to the first base 110. Accordingly, as shown in the graph in FIG. 9(c), when compared with the graph of Comparative Example, the temperature in the vicinity of (the vicinity of the light emission region 30a that corresponds to the waveguide 81) the Y-axis negative side in the arrangement direction of the five waveguides 81 to 85 is low.

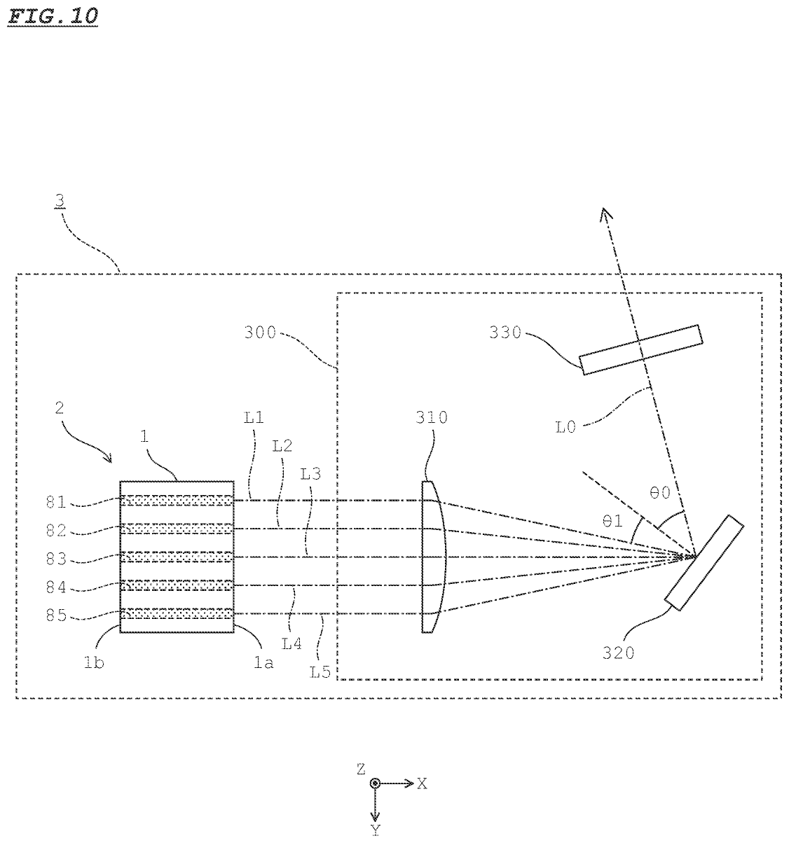

FIG. 10 is a top view schematically showing a basic configuration of an external resonance-type laser device 3. In FIG. 10, the five waveguides 81 to 85 of the semiconductor laser device 2 and the optical axes of beams emitted from the five waveguides 81 to 85 are shown. In FIG. 10, the alternate long and short dash lines indicate optical axes of laser beams emitted from the five waveguides 81 to 85. In FIG. 10, for convenience, only the semiconductor laser element 1 among the components of the semiconductor laser device 2 is shown.

The external resonance-type laser device 3 includes the semiconductor laser device 2 and an optical system 300. The optical system 300 includes an optical lens 310, a diffraction grating 320, and an output coupler 330.

The optical lens 310 is disposed so as to be opposed to the end face 1a of the semiconductor laser element 1, and condenses the five laser beams emitted in accordance with the five waveguides 81 to 85 of the semiconductor laser element 1, onto the incident surface of the diffraction grating 320. The optical lens 310 is a cylindrical lens, for example. In this case, the optical lens 310 is disposed such that the generatrix of the emission surface is parallel to the Z-axis.

The diffraction grating 320 performs wavelength beam combining on the five laser beams emitted from the five waveguides 81 to 85 of the semiconductor laser element 1. Specifically, when the wavelengths of the laser beams emitted from the waveguides 81 to 85 are wavelengths λ1 to λ5, respectively, the diffraction grating 320 causes the optical axes of these five laser beams to be aligned with each other so as to be directed to the output coupler 330. The diffraction grating 320 is a reflection-type diffraction grating. The direction in which diffraction grooves of the diffraction grating 320 extend is perpendicular to the arrangement direction (the Y-axis direction) of the five waveguides 81 to 85, and is parallel to the Z-axis direction.

In the diffraction grating 320, the diffraction grooves can be set such that the diffraction efficiency is high around the wavelengths λ1 to λ5. For example, when the optical axes of +1st order diffracted light of the laser beams having the wavelengths λ1 to λ5 are aligned by the diffraction grating 320, the diffraction grooves can be set such that the diffraction efficiency of the +1st order diffracted light of the beams having these wavelengths becomes high. The order of diffracted light for which the optical axes are aligned is not limited to +1st order, and may be another order.

The output coupler 330 is a partial reflector that reflects a part of the laser beams of which the optical axes are matched with each other by the diffraction grating 320. The output coupler 330 is disposed such that the reflection surface thereof is perpendicular to an optical axis L0 of the laser beam, after the wavelength beam combining, that is directed from the diffraction grating 320 toward the output coupler 330. The laser beam having passed through the output coupler 330 is emitted from the external resonance-type laser device 3, to be used in processing or the like.

The laser beams having the wavelengths λ1 to λ5 and reflected by the output coupler 330 go back in the optical path along the optical axis L0 to enter the diffraction grating 320. Then, the laser beams having the wavelengths λ1 to λ5 go back in the optical paths along the optical axes L1 to L5 of the emission time, and enter the waveguides 81 to 85, respectively. Accordingly, in the waveguides 81 to 85, resonances by the laser beams having the wavelengths λ1 to λ5 are induced, respectively, and the oscillation wavelengths at the waveguides 81 to 85 converge to the respective wavelengths λ1 to λ5.

Here, the incidence angle of the laser beams having the five wavelengths λi (i=1 to 5) that are incident from the optical lens 310 side on the diffraction grating 320 is defined as θi (i=1 to 5), and the emission angle of the laser beam reflected by the diffraction grating 320 is defined as θ0. In FIG. 10, for convenience, an incidence angle θ1 of the laser beam having the wavelength λ1 and emitted from the waveguide 81 and an emission angle θ0 that is common for the laser beams having the wavelengths λ1 to λ5 are shown. When the pitch (the interval between the diffraction grooves arranged in a direction perpendicular to the Z-axis) of the diffraction grooves of the diffraction grating 320 is defined as d, and the diffraction order is defined as m (integer), the relationship between the incidence angle θi, the emission angle θ0, the wavelength λi, the pitch d, and the diffraction order m is represented by formula (1) below.

d(sin θi−sin θ0)=mλi (1)

Here, the incidence angles θ1 to θ5 of the laser beams emitted from the waveguides 81 to 85 are determined in accordance with the interval between the waveguides 81 to 85 and the angles by which the optical axes L1 to L5 of the respective laser beams are bent by the optical lens 310. Therefore, in the optical system 300 in FIG. 10, the wavelengths λ1 to λ5 obtained from formula (1) above on the basis of the incidence angles θ1 to θ5 and the emission angle θ0 are the oscillation wavelengths at the five waveguides 81 to 85.

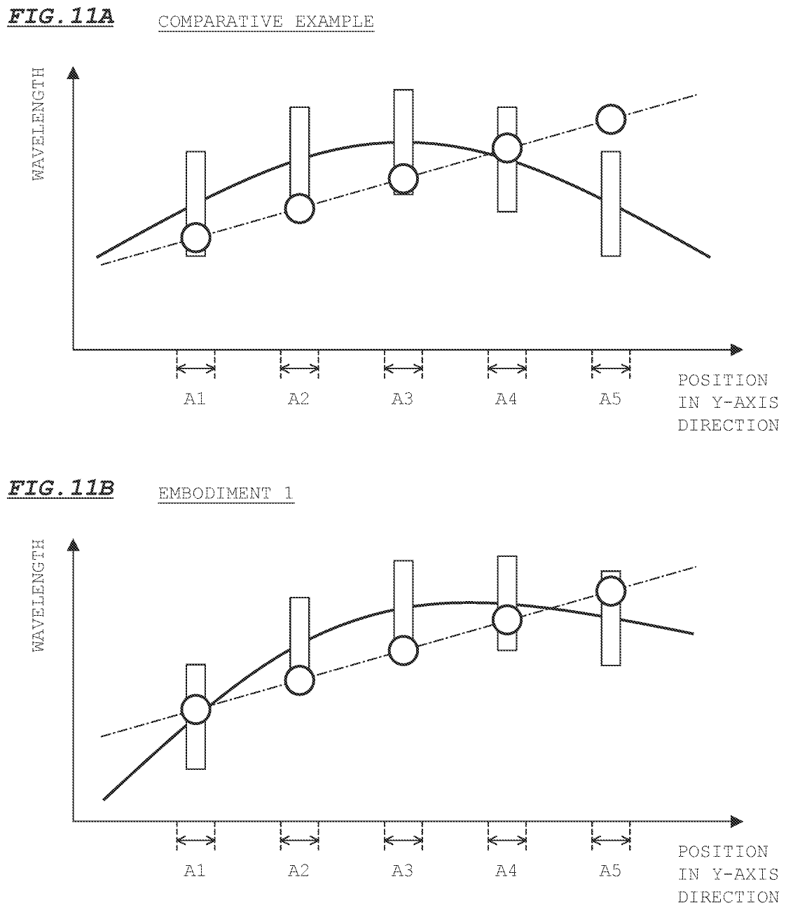

FIG. 11(a) is a schematic diagram showing the gain spectra at the respective waveguides 81 to 85 of the semiconductor laser element 1 and the oscillation wavelength by the external resonance-type laser device 3 according to Comparative Example. In FIG. 11(a), ranges λ1 to λ5 indicating the positions of the five waveguides 81 to 85 are shown. The wavelength according to the temperature and the thermal conductivity is indicated by a thick solid line, and the gain spectra of the oscillation wavelengths at the five waveguides 81 to 85 are indicated by rectangles in belt-like shapes. The oscillation wavelength by the external resonance-type laser device 3 is indicated by an alternate long and short dash line.

The gain spectra of the five waveguides 81 to 85 each have a width in the vertical axis direction, and the position in the vertical axis direction of the gain spectrum is shifted in accordance with the temperature. The gain spectrum is shifted to the long wave side when the temperature is high, and is shifted to the short wave side when the temperature is low. In Comparative Example in this case, as described with reference to FIG. 9(c), the Au composition ratio of the first adhesion layer 131 is constant regardless of the position in the Y-axis direction, similar to the second adhesion layer 220. Therefore, as shown in FIG. 9(c), in the Y-axis direction, the temperature in the vicinity of the center of the semiconductor laser element 1 becomes high. Thus, as shown in FIG. 11(a), the gain spectrum of the oscillation wavelength of the laser beam at the waveguide 83 at the center is positioned to the long wave side, and the gain spectra of the oscillation wavelengths of the laser beams at the waveguides 81, 85 at the ends are positioned to the short wave side.

The circles in FIG. 11(a) represent the oscillation wavelengths in Comparative Example at the five waveguides 81 to 85. As for the waveguides 81 to 84, the oscillation wavelength (the oscillation wavelength determined for each waveguide on the basis of formula (1) above) determined by the configuration of the optical system 300 is included in the range of the gain spectrum, and thus, laser oscillation can be efficiently realized at each oscillation wavelength. Meanwhile, as for the waveguide 85, the oscillation wavelength determined by the configuration of the optical system 300 is significantly separated from the gain spectrum. Therefore, in the waveguide 85, a problem that the light emission efficiency of laser is significantly decreased, or laser oscillation does not occur, is caused.

FIG. 11(b) is a schematic diagram showing the gain spectra at the respective waveguides 81 to 85 of the semiconductor laser element 1 and the oscillation wavelength by the external resonance-type laser device 3 according to Embodiment 1.

In the case of Embodiment 1, as shown in FIG. 9(c), the temperature in the vicinity of the Y-axis negative side of the semiconductor laser element 1 is low, and the temperature in the vicinity of the Y-axis positive side of the semiconductor laser element 1 is high. Therefore, the gain spectra of the waveguides 81, 82 positioned on the Y-axis negative side are shifted to the short wave side, and the gain spectra of the waveguides 84, 85 positioned on the Y-axis positive side are shifted to the long wave side. As a result, in each of the five waveguides 81 to 85, the oscillation wavelength determined by the optical system 300 is included in the range of the gain spectrum. Therefore, in all of the five waveguides 81 to 85, laser oscillation efficiently occurs at the oscillation wavelength determined by the optical system 300.

<Effect of Embodiment 1>

According to Embodiment 1, the following effects are exhibited.

In the external resonance-type laser device 3, the oscillation wavelengths at the respective waveguides 81 to 85 of the semiconductor laser device 2 are determined by the configuration (the incidence angle to the diffraction grating 320) of the optical system 300. Therefore, the oscillation wavelengths at the respective waveguides 81 to 85 vary in one direction in accordance with the positions of the waveguides 81 to 85. In Embodiment 1, the oscillation wavelength of the semiconductor laser device 2 gradually changes to a long wave, from the waveguide 81 on the one end portion side (the Y-axis negative side) toward the waveguide 85 on the other end portion side (the Y-axis positive side).

Meanwhile, at the time of light emission operation of the semiconductor laser element 1, heat is generated at the light emission regions 30a corresponding to the respective waveguides 81 to 85. The generated heat moves from the semiconductor laser element 1 via the first adhesion layer 131 to the first base 110 and is dissipated from the first base 110. Here, when the thermal conductivity of the first adhesion layer 131 is constant regardless of the position, the heat generated in the light emission regions 30a corresponding to the respective waveguides 81 to 85 causes mutual interference, whereby the temperature in the vicinity of the center of the semiconductor laser element 1 in the arrangement direction of the waveguides 81 to 85 becomes high. As a result, the gain spectrum necessary for oscillation becomes a long wave at the waveguide 83 at the center, and becomes a short wave at each of the waveguides 81, 85 at the ends. In such a state, for example, as shown in FIG. 11(a), in the waveguide 85, a mismatch can be caused between the oscillation wavelength determined by the configuration of the optical system 300 and the gain spectrum determined by the temperature distribution.

In contrast to this, according to Embodiment 1, the thermal conductivity of the first adhesion layer 131 is, in the arrangement direction of the waveguides 81 to 85, higher on the one end portion side (the Y-axis negative side) than on the other end portion side (the Y-axis positive side). Accordingly, movement of heat to the first base 110 is promoted in the vicinity of the Y-axis negative side of the semiconductor laser element 1. Accordingly, the temperature on the Y-axis positive side becomes higher than the temperature on the Y-axis negative side. As a result, the gain spectrum of the waveguide 85 positioned on the Y-axis positive side becomes a longer wave than the gain spectrum of the waveguide 81 positioned on the Y-axis negative side. Therefore, the distribution of the gain spectra in the Y-axis direction comes to agree with the oscillation wavelengths determined by the configuration of the optical system 300. Accordingly, the oscillation wavelengths determined by the configuration of the optical system 300 can be caused to fall in the ranges of the gain spectra determined by the temperature distribution. Therefore, decrease in the light emission efficiency at each waveguide 81 to 85 of the semiconductor laser device 2 can be suppressed.

When the semiconductor laser device 2 is configured as described above, decrease in the light emission efficiency at each waveguide 81 to 85 is suppressed. Therefore, the efficiency of laser oscillation can be enhanced in the external resonance-type laser device 3. Accordingly, the quality of the laser beam outputted from the external resonance-type laser device 3 is enhanced, and work such as processing using the laser beam can be smoothly performed.

The Au composition ratios in the vicinity of the Y-axis positive side and in the vicinity of the Y-axis negative side of the first adhesion layer 131 are not limited to those described above. In the semiconductor laser element 1, in a case where the temperature on the Y-axis negative side becomes lower than the temperature on the Y-axis positive side, whereby the oscillation wavelengths determined by the configuration of the optical system 300 fall in the ranges of the gain spectra, which change in accordance with the temperature, the Au composition ratios may be set to values different from those described above.

The semiconductor laser element 1 is mounted in a junction down manner in the semiconductor laser device 2 via the first base 110. Accordingly, heat generated in the semiconductor laser element 1 can be smoothly moved to the package or the like of the semiconductor laser device 2 via the first adhesion layer 131 and the first base 110. Therefore, as shown in FIG. 9(c), the temperature distribution of the semiconductor laser element 1 can be smoothly set such that the temperature is lower on the Y-axis negative side than on the Y-axis positive side. Thus, the distribution of the gain spectra in the Y-axis direction can be smoothly set so as to agree with the oscillation wavelengths determined by the configuration of the optical system 300.

### Embodiment 2

In Embodiment 1, the thermal conductivity of the first adhesion layer 131 is gently increased from the Y-axis positive side toward the Y-axis negative side as shown in FIG. 9(b). In contrast to this, in Embodiment 2, the thermal conductivity of the first adhesion layer 131 is increased stepwise from the Y-axis positive side toward the Y-axis negative side.

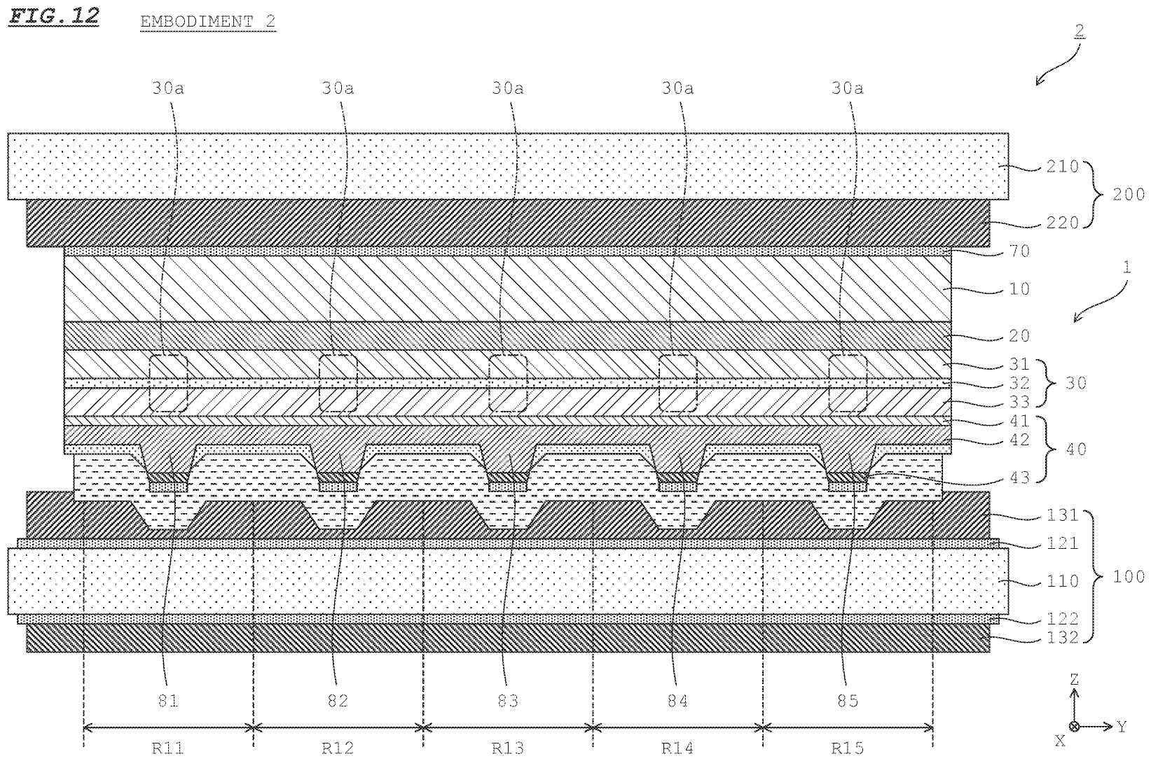

FIG. 12 is a cross-sectional view schematically showing a configuration of the semiconductor laser device 2 of Embodiment 2.

In Embodiment 2, only the Au composition ratio of the first adhesion layer 131 is different when compared with Embodiment 1. Regions R11 to R15 shown in FIG. 12 are portions of the first adhesion layer 131 that correspond to the five waveguides 81 to 85. The positions in the Y-axis direction of the five regions R11 to R15 respectively include the positions in the Y-axis direction of the five waveguides 81 to 85. The widths in the Y-axis direction of the five regions R11 to R15 are equal to each other. The thermal conductivities of the five regions R11 to R15 of the first adhesion layer 131 are increased stepwise from the Y-axis positive side toward the Y-axis negative side.

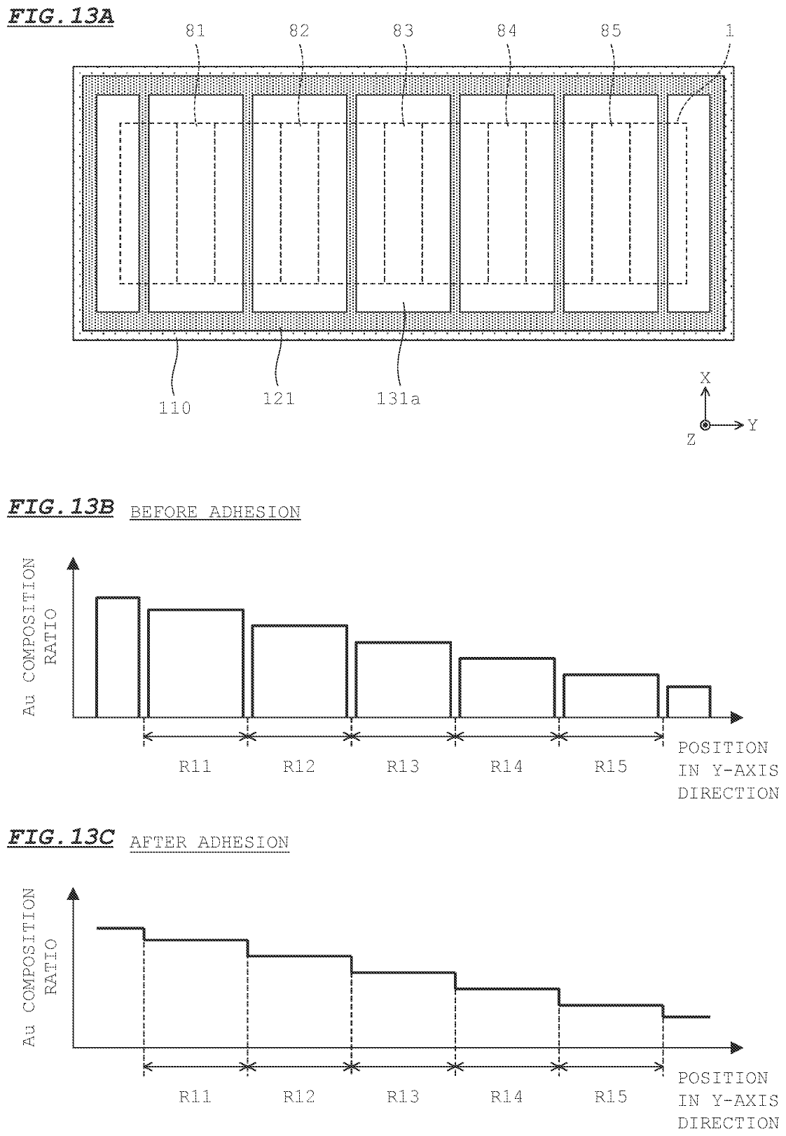

FIG. 13(a) is a top view schematically showing solder members 131a disposed on the first base 110.

When the semiconductor laser element 1 is to be adhered to the first electrode 121 on the first base 110, a plurality of solder members 131a are disposed on the first electrode 121 as shown in FIG. 13(a). In FIG. 13(a), seven solder members 131a are arranged in the Y-axis direction. In the five solder members 131a positioned at the center, the widths in the Y-axis direction are substantially the same as the widths in the Y-axis direction of the five regions R11 to R15 in FIG. 12, and the length in the X-axis direction is longer than that of the semiconductor laser element 1. After the plurality of solder members 131a are disposed as in FIG. 13(a), all of the solder members 131a are melted by heat, and then, the semiconductor laser element 1 is disposed on solder members 131a. Accordingly, the semiconductor laser element 1 and the first electrode 121 are adhered to each other by means of the solder members 131a, and the plurality of solder members 131a are connected to each other in the Y-axis direction, thereby becoming the first adhesion layer 131.

FIG. 13(b) is a graph showing the Au composition ratio of the plurality of solder members 131a arranged in the Y-axis direction. In the graph in FIG. 13(b), positions corresponding to the regions R11 to R15 are also shown.

In Embodiment 2 as well, similar to Embodiment 1, the Au composition ratios of solder members 131a adjacent to each other are different from each other, but the Au composition ratio in a single solder member 131a is constant. The Au composition ratios of the seven solder members 131a are different in accordance with the positions in the Y-axis direction.

FIG. 13(c) is a graph showing the Au composition ratio of the first adhesion layer 131 after the semiconductor laser element 1 and the first electrode 121 have been adhered.

When the Au composition ratios of the plurality of solder members 131a have been set as shown in FIG. 13(b), and these solder members 131a have been melted by heat, thereby adhering the semiconductor laser element 1 and the first electrode 121 to each other, the formed first adhesion layer 131 has an Au composition ratio as shown in FIG. 13(c).

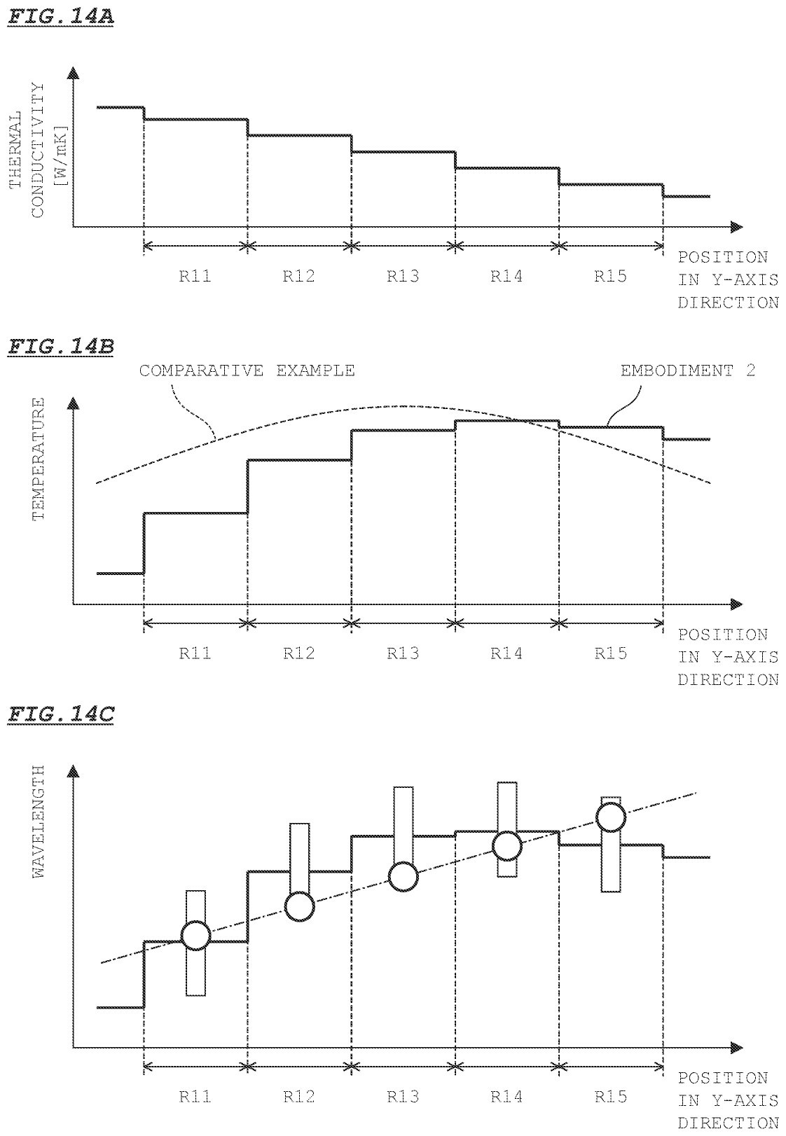

In Embodiment 2, since the width in the Y-axis direction of each solder member 131a is greater than in Embodiment 1, the Au composition ratio of the first adhesion layer 131 after the adhesion is in a stepped shape in accordance with the position in the Y-axis direction. That is, the Au composition ratios of the five regions R11 to R15 of the first adhesion layer 131 are increased stepwise from the Y-axis positive side toward the Y-axis negative side in the Y-axis direction. Therefore, the thermal conductivity of the first adhesion layer 131 of Embodiment 2 is set in a stepped shape as shown in FIG. 14(a). That is, the thermal conductivities of the five regions R11 to R15 of Embodiment 2 are increased stepwise from the Y-axis positive side toward the Y-axis negative side.

When the thermal conductivity of the first adhesion layer 131 is set as shown in FIG. 14(a), heat in the vicinity of the Y-axis negative side of the semiconductor laser element 1 is smoothly conducted to the first base 110 and removed, as in Embodiment 1. Accordingly, as shown in the graph of Embodiment 2 in FIG. 14(b), when compared with the graph of Comparative Example, the temperature in the vicinity of the Y-axis negative side is low and the temperature in the vicinity of the Y-axis positive side is high. Therefore, as shown in the graph in FIG. 14(c), the oscillation wavelengths determined by the configuration of the optical system 300 fall in the ranges of the gain spectra of the five waveguides 81 to 85.

As described above, according to Embodiment 2, as in Embodiment 1, the thermal conductivity of the first adhesion layer 131 is higher on the Y-axis negative side than on the Y-axis positive side. Accordingly, the oscillation wavelengths determined by the configuration of the optical system 300 can be caused to fall in the ranges of gain spectra of the five waveguides 81 to 85. Therefore, decrease in the light emission efficiency at each waveguide 81 to 85 of the semiconductor laser device 2 can be suppressed.

According to Embodiment 2, in the five regions R11 to R15 of the first adhesion layer 131, the thermal conductivity in each region R11 to R15 is constant as shown in FIG. 14(a). Accordingly, the temperature, of the semiconductor laser element 1, that corresponds to the position of each of the five regions R11 to R15 becomes substantially constant in the region, as shown in FIG. 14(b). Therefore, in the light emission layer 30 (the light emission region 30a) that corresponds to each waveguide 81 to 85, the temperatures at the end portion on the Y-axis positive side and at the end portion on the Y-axis negative side of the light emission region 30a can be substantially the same with each other. Accordingly, in each light emission region 30a, a situation where deterioration advances from one side in the Y-axis direction can be avoided. Therefore, deterioration of the light emission layer 30 corresponding to each waveguide 81 to 85 can be suppressed. Therefore, reliability of the semiconductor laser device 2 can be improved.

### Embodiment 3

In Embodiment 2, in order to vary the thermal conductivity of the first adhesion layer 131 in the Y-axis direction, the first adhesion layer 131 is formed by a plurality of solder members 131a of which the thermal conductivities are set as shown in FIG. 13(b). In contrast to this, in Embodiment 3, heat insulation parts for blocking heat to be conducted in the first adhesion layer 131 are further provided between a plurality of solder members 131a that are similar to those in Embodiment 2.

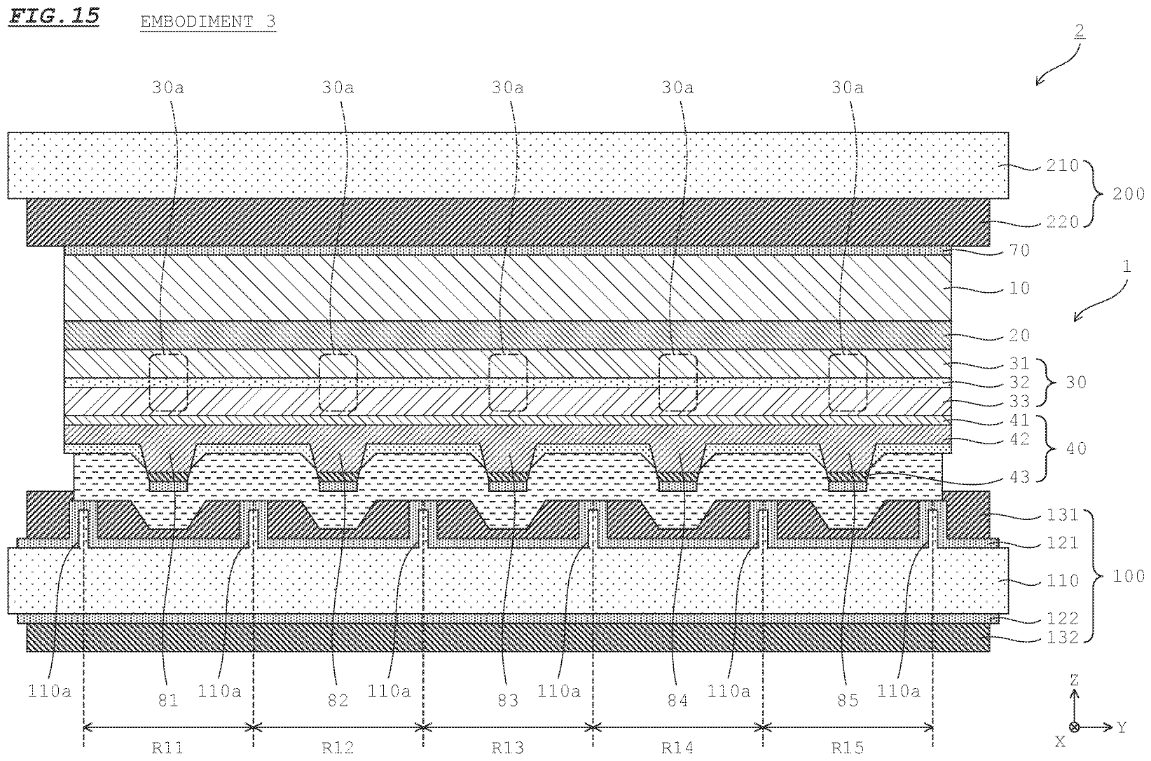

FIG. 15 is a cross-sectional view schematically showing a configuration of the semiconductor laser device 2 of Embodiment 3.

In Embodiment 3, when compared with Embodiment 2, in order to block heat between the regions R11 to R15 of the first adhesion layer 131, six protrusion parts 110a are provided as heat insulation parts. The protrusion parts 110a are provided, in the regions R11 to R15 of the first adhesion layer 131, at end portions in the Y-axis direction of the regions. That is, the six protrusion parts 110a are provided at boundary portions of the regions R11 to R15 on the upper face (the face on the Z-axis positive side), of the first base 110, that faces the semiconductor laser element 1.

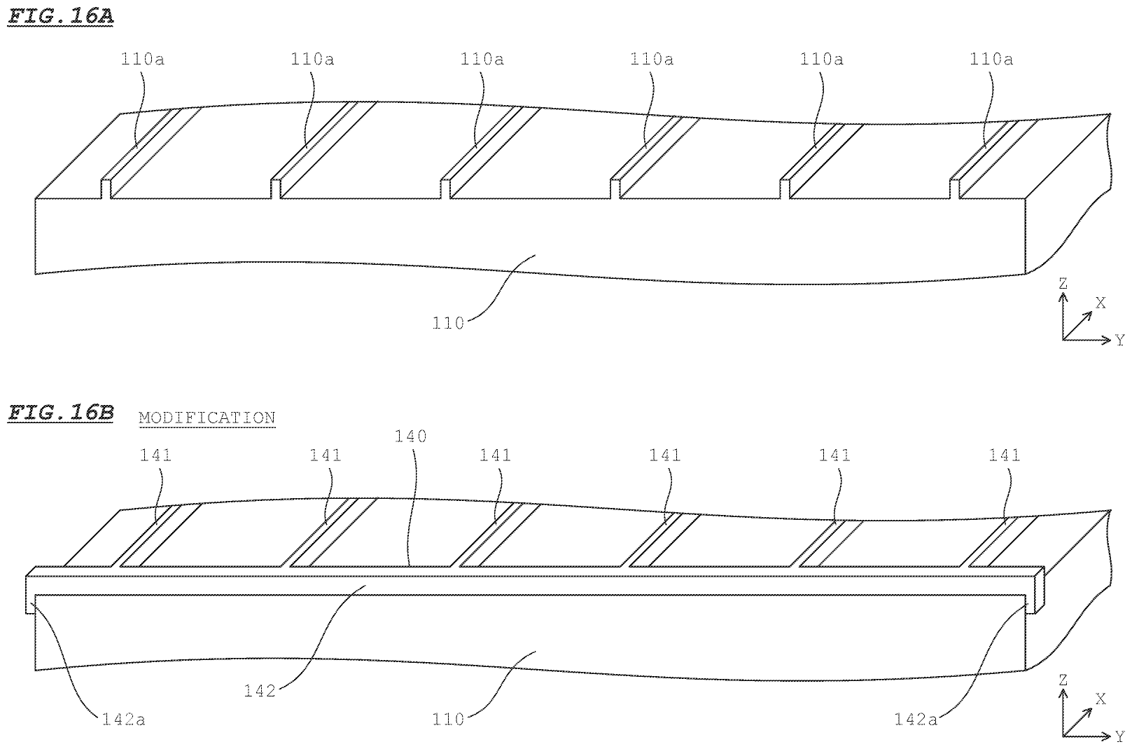

FIG. 16(a) is a perspective view schematically showing configurations of the protrusion parts 110a.

The six protrusion parts 110a are configured such that the width in the Y-axis direction is small, and the length in the X-axis direction is substantially the same as the length in the X-axis direction of the first base 110. On the upper face of the first base 110, regions other than the regions corresponding to the protrusion parts 110a are removed by etching, whereby the six protrusion parts 110a are formed.

In Embodiment 3, the first electrode 121 is formed through vapor deposition on the upper face of the first base 110 where the six protrusion parts 110a are formed as shown in FIG. 16(a). As a result, as shown in FIG. 15, the upper face of the first base 110 is covered by the first electrode 121. Then, as in Embodiment 2, the plurality of solder members 131a of which the Au composition ratios are set as shown in FIG. 13(b) are disposed on the upper faces, of the first base 110 as shown in FIG. 13(a), that correspond to the regions R11 to R15, and the semiconductor laser element 1 and the first base 110 are adhered by means of the first adhesion layer 131. That is, the solder members 131a are disposed in the respective regions sectioned by the protrusion parts 110a, and the semiconductor laser element 1 and the first base 110 are adhered by means of the first adhesion layer 131. As a result, as shown in FIG. 15, the five regions R11 to R15 of the first adhesion layer 131 are sectioned by the protrusion parts 110a.

According to Embodiment 3, a protrusion part 110a is provided between adjacent two regions of the first adhesion layer 131. Thus, movement of heat between the adjacent two regions is suppressed by the protrusion part 110a. As a result, the temperature in the light emission region 30a corresponding to each waveguide 81 to 85 can be caused to be further uniform. Therefore, deterioration of the light emission layer 30 corresponding to each waveguide 81 to 85 can be further suppressed when compared with Embodiment 2.

The protrusion parts 110a are provided to the first base 110, as the heat insulation parts for blocking heat to be conducted in the first adhesion layer 131. When the heat insulation parts are implemented as the protrusion parts 110a, the heat insulation parts can be accurately and easily formed.

<Modification of Embodiment 3>

In Embodiment 3, as the heat insulation part for blocking heat to be conducted between adjacent two regions of the first adhesion layer 131, the protrusion part 110a is provided to the first base 110. However, the configuration of the heat insulation part is not limited thereto. For example, as shown in FIG. 16(b), a partition member 140 may be provided instead of the protrusion part 110a.

FIG. 16(b) is a perspective view schematically showing a configuration of the partition member 140 of the present modification.

The partition member 140 includes six wall parts 141 extending in the X-axis direction, and two support parts 142 each connecting the six wall parts 141 and extending in the Y-axis direction. The two support parts 142 are provided at end portions on the X-axis positive side and the X-axis negative side of the wall parts 141. In FIG. 16(b), out of the two support parts 142, only the support part 142 on the X-axis negative side is shown. A flange portion 142a projecting in the Z-axis negative direction is provided to each of end portions on the Y-axis positive side and the Y-axis negative side of each support part 142. The partition member 140 is disposed on the upper face of the first base 110 such that the two flange portions 142a are respectively caught by the side face on the Y-axis positive side and the side face on the Y-axis negative side of the first base 110. Accordingly, the wall parts 141 can be easily positioned to the positions similar to those of the protrusion parts 110a of Embodiment 3.

In the present modification, the partition member 140 is disposed on the first base 110 as shown in FIG. 16(b), and then, the first electrode 121 is formed through vapor deposition on the upper face of the first base 110. Alternatively, before the partition member 140 is disposed on the first base 110, the first electrode 121 may be formed through vapor deposition on the upper face of the first base 110, and then, the partition member 140 may be disposed on the upper face (the upper face of the first electrode 121) of the first base 110.

According to the present modification, a wall part 141 of the partition member 140 is provided between adjacent two regions of the first adhesion layer 131. Therefore, movement of heat between the adjacent two regions is suppressed by the wall part 141. Therefore, as in Embodiment 3, the temperature in the light emission region 30a corresponding to each waveguide 81 to 85 can be caused to be uniform.

### Embodiment 4

In Embodiment 3, in order to block conduction of heat between the regions R11 to R15 of the first adhesion layer 131, the heat insulation parts (protrusion parts 110a) are provided. In contrast to this, in Embodiment 4, the thermal conductivity of the second adhesion layer 220 is set so as to be increased stepwise from the Y-axis positive side toward the Y-axis negative side, and heat insulation parts for blocking conduction of heat between regions R21 to R25 of the second adhesion layer 220 are provided.

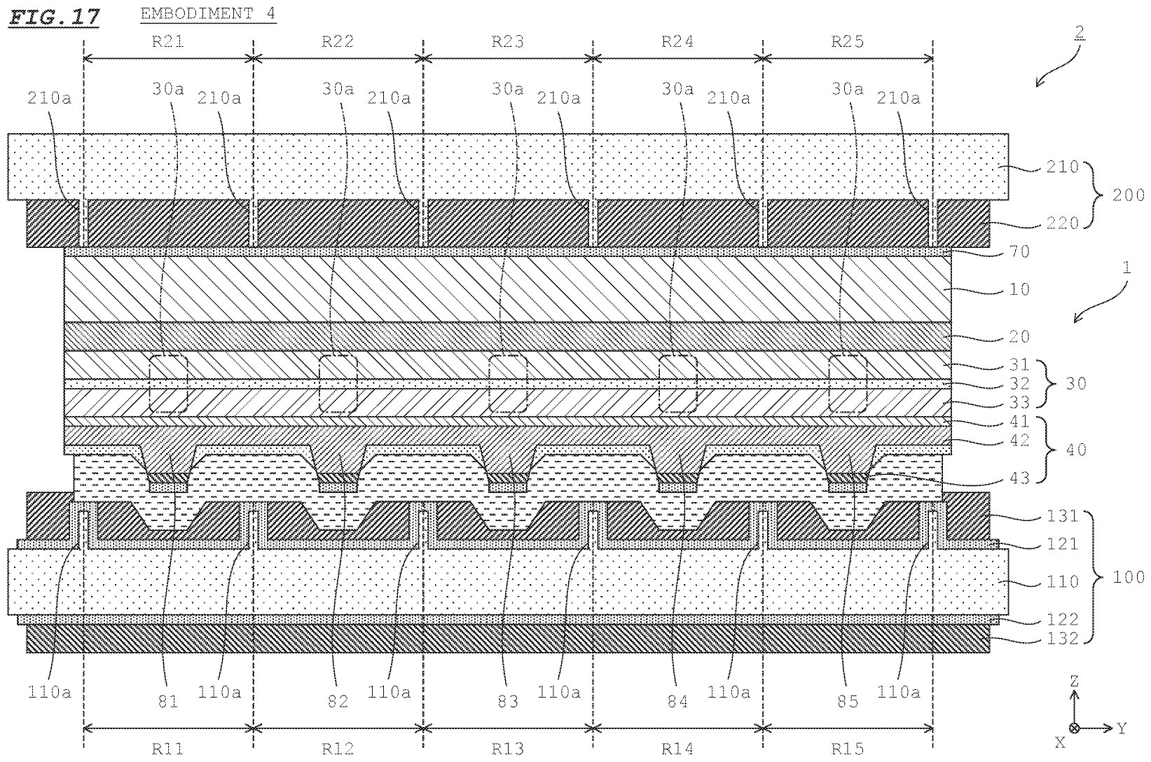

FIG. 17 is a cross-sectional view showing a configuration of the semiconductor laser device 2 of Embodiment 4.

The regions R21 to R25 shown in FIG. 17 are portions of the second adhesion layer 220 that correspond to the five waveguides 81 to 85. The positions and widths in the Y-axis direction of the five regions R21 to R25 are the same as those of the five regions R11 to R15 of Embodiments 2, 3. The thermal conductivity of the five regions R21 to R25 of the second adhesion layer 220 is increased stepwise from the Y-axis positive side toward the Y-axis negative side, similar to the thermal conductivity of the five regions R11 to R15 of Embodiments 2, 3.

In Embodiment 4, in order to block heat to be conducted between the regions R21 to R25 of the second adhesion layer 220, six protrusion parts 210a are provided as heat insulation parts to the second base 210. The six protrusion parts 210a are provided at the same positions, in the Y-axis direction, as those of the six protrusion parts 110a.

According to Embodiment 4, the thermal conductivity of the second adhesion layer 220 is higher on the Y-axis negative side than on the Y-axis positive side. Accordingly, in addition to the effects provided by the first adhesion layer 131, movement of heat to the second base 210 is further promoted in the vicinity of the Y-axis negative side of the semiconductor laser element 1. Therefore, the temperature distribution in the arrangement direction (the Y-axis direction) of the five waveguides 81 to 85 can be smoothly set such that the temperature is lower on the Y-axis negative side than on the Y-axis positive side. Thus, the center wavelength of the gain spectrum of each waveguide 81 to 85 can be caused to be further close to the oscillation wavelength determined by the configuration of the optical system 300. Therefore, decrease in the light emission efficiency at each waveguide 81 to 85 of the semiconductor laser device 2 can be further suppressed.

According to Embodiment 4, similar to the first adhesion layer 131 of Embodiments 2, 3, in each of the five regions R21 to R25 of the second adhesion layer 220, the thermal conductivity in the region is constant. In addition, the protrusion parts 210a are provided between adjacent regions of the second adhesion layer 220. As a result, movement of heat between adjacent regions of the second adhesion layer 220 is further suppressed, and the temperatures at the end portion on the Y-axis positive side and the end portion on the Y-axis negative side of the light emission region 30a can be caused to be further close to each other. Accordingly, the temperature in the light emission region 30a corresponding to each waveguide 81 to 85 becomes further uniform. Therefore, deterioration of the light emission layer 30 with respect to each waveguide 81 to 85 can be further suppressed.

### OTHER MODIFICATIONS

Although the embodiments of the present invention have been described, the present invention is not limited to the above embodiments, and various other modifications can be made.

For example, in Embodiments 1 to 3, the thermal conductivity of the second adhesion layer 220 is constant regardless of the position in the Y-axis direction. However, similar to the first adhesion layer 131 of Embodiments 1 to 3, the thermal conductivity of the second adhesion layer 220 may be varied in accordance with the position in the Y-axis direction.

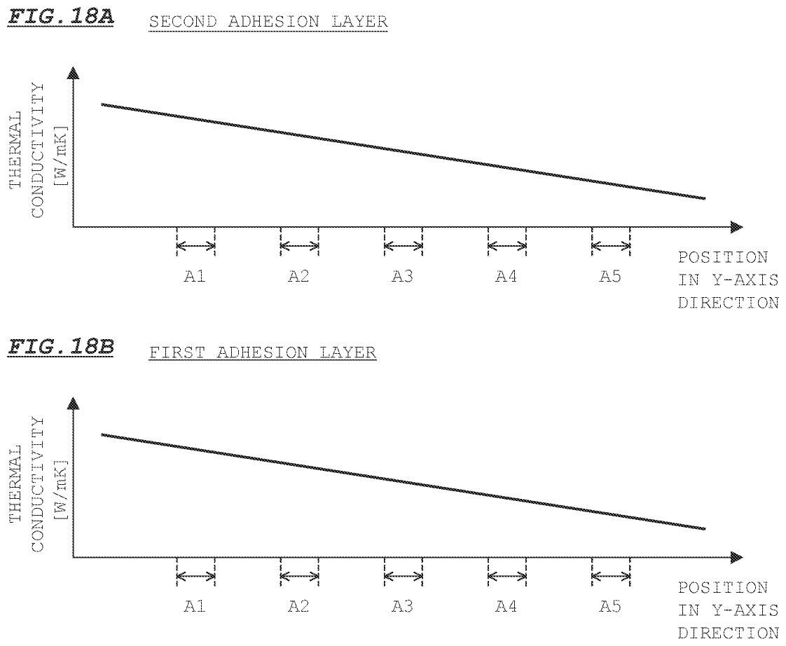

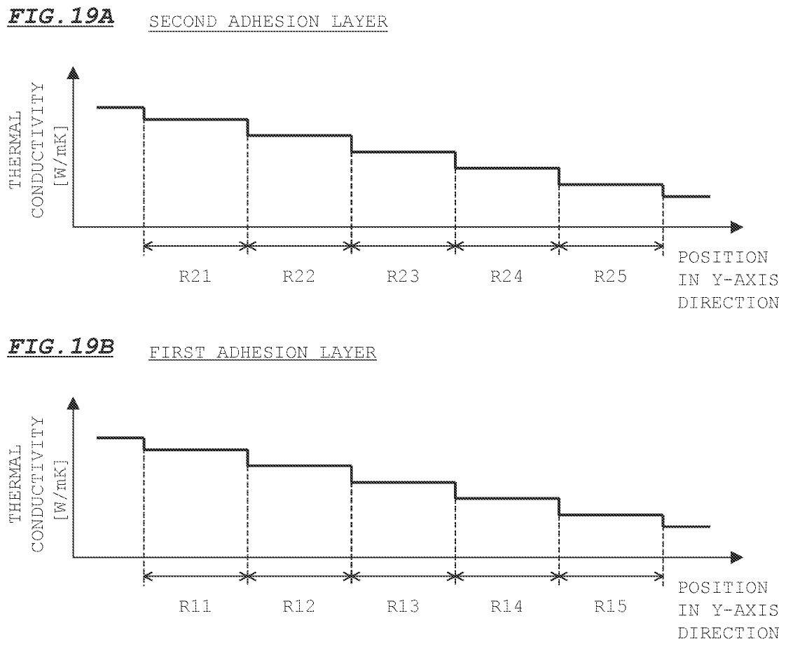

That is, similar to the first adhesion layer 131 of Embodiment 1, the thermal conductivity of the second adhesion layer 220 may be increased from the Y-axis positive side toward the Y-axis negative side, as shown in FIG. 18(a). In this case, the thermal conductivity of the first adhesion layer 131 is set, for example, so as to be similar to that in Embodiment 1 as shown in FIG. 18(b). Alternatively, the thermal conductivity of the second adhesion layer 220 may be, similar to the first adhesion layer 131 of Embodiments 2, 3, increased stepwise from the Y-axis positive side toward the Y-axis negative side as shown in FIG. 19(a). In this case, the thermal conductivity of the first adhesion layer 131 is set, for example, so as to be similar to that in Embodiments 2, 3 as shown in FIG. 19(b).

As described above, with respect to the thermal conductivity of the second adhesion layer 220 as well, when the thermal conductivity of the second adhesion layer 220 is caused to be higher in the vicinity of the Y-axis negative side than in the vicinity of the Y-axis positive side, movement of heat in the vicinity of the Y-axis negative side of the semiconductor laser element 1 is further promoted. Therefore, the temperature distribution in the arrangement direction (the Y-axis direction) of the five waveguides 81 to 85 can be smoothly set such that the temperature is lower on the Y-axis negative side than on the Y-axis positive side. Thus, the center wavelength of the gain spectrum of each waveguide 81 to 85 can be caused to be further close to the oscillation wavelength determined by the configuration of the optical system 300. Therefore, decrease in the light emission efficiency at each waveguide 81 to 85 of the semiconductor laser device 2 can be further suppressed.

In Embodiments 1 to 4, the thermal conductivity of the first adhesion layer 131 is varied in accordance with the position in the Y-axis direction. However, similar to the thermal conductivity of the second adhesion layer 220 of Embodiment 1, the thermal conductivity of the first adhesion layer 131 may be constant regardless of the position in the Y-axis direction. In this case, the thermal conductivity of the second adhesion layer 220 is set so as to be varied in accordance with the position in the Y-axis direction, similar to the first adhesion layer 131 of Embodiments 1 to 3.

As described above, preferably, in at least one of the first adhesion layer 131 on the submount 100 side and the second adhesion layer 220 on the submount 200 side, the thermal conductivity is set so as to be varied in accordance with the position in the Y-axis direction. Accordingly, the temperature on the Y-axis negative side of the semiconductor laser element 1 becomes lower than on the Y-axis positive side, and thus, the center wavelength of the gain spectrum of each waveguide 81 to 85 can be caused to be further close to the oscillation wavelength determined by the configuration of the optical system 300.

In the semiconductor laser element 1, the temperature easily rises on the face on the p side (waveguide side). Therefore, it is preferable that, in the adhesion layer to which the p side of the semiconductor laser element 1 is directed, the thermal conductivity on the Y-axis positive side is increased. That is, as in Embodiments 1 to 4, when the semiconductor laser element 1 is disposed in a junction down manner, the thermal conductivity on the Y-axis negative side of the first adhesion layer 131 is preferably increased. Accordingly, deterioration of the light emission layer 30 in each waveguide 81 to 85 can be smoothly suppressed. However, when the semiconductor laser element 1 is disposed in a junction up manner, heat of the semiconductor laser element 1 easily moves to the first base 110 side via the first adhesion layer 131, and thus, it is preferable that the thermal conductivity on the Y-axis negative side of the first adhesion layer 131 is increased.

In the above embodiments, five waveguides are provided to the semiconductor laser element 1. However, not limited thereto, 1 to 4 or 6 or more waveguides may be provided.

In the above embodiments, an electrode similar to the first electrode 121 may be provided between the second base 210 and the second adhesion layer 220.

In the above embodiments, the submount 200 is provided in order to dissipate the heat generated in the light emission layer 30, from the n-side face (the face on the substrate 10 side of the semiconductor laser element 1). However, when there is no need to enhance heat dissipation performance by the submount 200, the second adhesion layer 220 may be omitted. In this case, in order to electrically connect the n-side electrode 70 and the second base 210, an electrode similar to the first electrode 121 is provided. When there is no need to provide heat dissipation by use of the submount 200, the submount 200 itself may be omitted. In this case, feeding wiring may be provided to the n-side electrode 70 by performing wire bonding directly on the n-side electrode 70 of the semiconductor laser element 1.

In the above embodiments, the semiconductor laser element 1 is disposed in the semiconductor laser device 2 in a junction down manner in which the p side (the waveguides 81 to 85 side) of the semiconductor laser element 1 is connected to the submount 100. However, not limited thereto, the semiconductor laser element 1 may be disposed in the semiconductor laser device 2 in a junction up manner in which the n side (the n-side electrode 70) of the semiconductor laser element 1 is connected to the submount 100.

In the above embodiments, as shown in FIG. 9(b) and FIG. 14(a), the thermal conductivity of the first adhesion layer 131 is set so as to extend along a straight line in which the thermal conductivity is increased toward the Y-axis negative direction. However, not limited thereto, the thermal conductivity of the first adhesion layer 131 may be set so as to extend along a curve in which the thermal conductivity is increased toward the Y-axis negative direction.

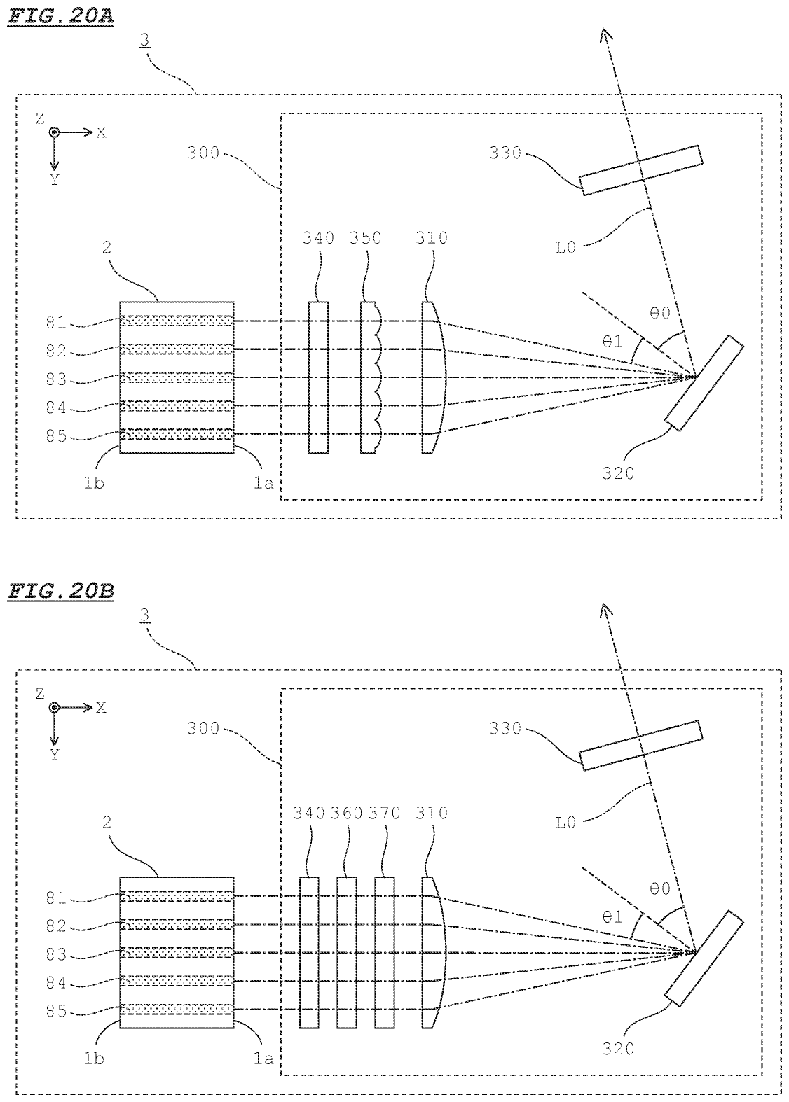

In the above embodiments, the external resonance-type laser device 3 is configured as shown in FIG. 10. However, not limited thereto, the external resonance-type laser device 3 may be configured as shown in FIG. 20(a) or FIG. 20(b).

In the modification shown in FIG. 20(a), a fast axis cylindrical lens 340 and a slow axis cylindrical lens 350 are disposed between the semiconductor laser device 2 and the optical lens 310.

Here, the axis in the direction perpendicular to the light emission layer 30 (see FIG. 6) of the semiconductor laser element 1 is referred to as a fast axis, and the axis in the direction parallel to the light emission layer 30 is referred to as a slow axis. Each laser beam emitted from the end face 1a has a greater angle of divergence in the fast axis direction than in the slow axis direction. Therefore, the shape of the beam emitted from the end face 1a becomes an elliptical shape that is long in the fast axis direction.

The incident surface of the fast axis cylindrical lens 340 is a plane that is parallel to the Y-Z plane, and the emission surface of the fast axis cylindrical lens 340 is a curved plane that is curved only in the direction parallel to the X-Z plane. The generatrix of the emission surface of the fast axis cylindrical lens 340 is parallel to the Y-axis. The fast axis cylindrical lens 340 converges each laser beam emitted from the end face 1a into the fast axis direction (the Z-axis direction), thereby adjusting the divergence of the laser beam to a substantially collimated state.

The incident surface of the slow axis cylindrical lens 350 is a plane that is parallel to the Y-Z plane, and the emission surface of the slow axis cylindrical lens 350 is a curved plane that is curved only in the direction parallel to the X-Y plane at the positions where the five laser beams pass. The generatrix of the emission surface at the positions, where the five laser beams pass, of the slow axis cylindrical lens 350 is parallel to the Z-axis. The slow axis cylindrical lens 350 converges each laser beam having passed through the fast axis cylindrical lens 340, into the slow axis direction (the Y-axis direction), thereby adjusting the divergence of the laser beam in the slow axis direction to a substantially collimated state.

As described above, as a result of each laser beam passing through the fast axis cylindrical lens 340 and the slow axis cylindrical lens 350, the laser beam becomes a substantially collimated beam and enters the optical lens 310. Accordingly, a greater amount of each laser beam emitted from the semiconductor laser element 1 can be guided to the output coupler 330, and a greater amount of the laser beam reflected by the output coupler 330 can be returned to the semiconductor laser element 1. Therefore, efficient resonance of laser can be realized in the external resonance-type laser device 3, and emission efficiency of the laser beam emitted from the external resonance-type laser device 3 can be enhanced.

In the modification shown in FIG. 20(b), when compared with the modification shown in FIG. 20(a), an image rotating lens 360 and a slow axis cylindrical lens 370 are disposed instead of the slow axis cylindrical lens 350.

The image rotating lens 360 rotates each laser beam having passed through the fast axis cylindrical lens 340, by about 90° around the optical axis. Accordingly, the fast axis of the laser beam is converted from the direction parallel to the Z-axis, to the direction parallel to the Y-axis, and the slow axis of the laser beam is converted from the direction parallel to the Y-axis, to the direction parallel to the Z-axis. When the direction of the fast axis and the direction of the slow axis of the laser beam are interchanged, the slow axis direction of the laser beam is converted from the state of being parallel to the arrangement direction of the laser beams emitted from the end face 1a, to a state of being perpendicular to the arrangement direction. Therefore, the divergence direction of the laser beam becomes a direction perpendicular to the arrangement direction of the laser beams. Accordingly, interference in the Y-axis direction between the five laser beams directed toward the slow axis cylindrical lens 370 is suppressed.

The incident surface of the slow axis cylindrical lens 370 is a plane that is parallel to the Y-Z plane, and the emission surface of the slow axis cylindrical lens 370 is a curved plane that is curved only in the direction parallel to the X-Z plane. The generatrix of the emission surface of the slow axis cylindrical lens 370 is parallel to the Y-axis. The slow axis cylindrical lens 370 converges each laser beam having passed through the image rotating lens 360, into the slow axis direction (the Z-axis direction), thereby adjusting the divergence of the laser beam in the slow axis direction to a substantially collimated state.

In this case as well, each laser beam becomes a substantially collimated beam and enters the optical lens 310. As a result, efficient resonance of laser can be realized in the external resonance-type laser device 3, and emission efficiency of the laser beam emitted from the external resonance-type laser device 3 can be enhanced.

In the above embodiments, a condenser lens for condensing the laser beam may be disposed on the emission side (the side of the face opposite to the face facing the diffraction grating 320) of the output coupler 330. In the above embodiments, the diffraction grating 320 is a reflection-type diffraction grating, but the diffraction grating 320 may be a transmission-type diffraction grating. As the diffraction grating 320, a blazed diffraction grating, a stepped diffraction grating, or the like can be used. In the above embodiments, the optical lens 310 is a cylindrical lens, but the optical lens 310 may be a spherical lens, an aspherical lens, a Fresnel lens, or the like. The optical lens 310 may be combined with a lens that suppresses chromatic aberration.

In the above embodiments, the first adhesion layer 131 and the second adhesion layer 220 are formed of gold and tin. However, the elements forming the first adhesion layer 131 and the second adhesion layer 220 are not limited to gold and tin. Among a plurality of elements that form the first adhesion layer 131 and the second adhesion layer 220, an element that has a higher thermal conductivity is not limited to gold, and may be silver or copper. Even when the element that has the higher thermal conductivity is an element other than gold, the first adhesion layer 131 and the second adhesion layer 220 are configured such that, in the arrangement direction of the plurality of waveguides, the composition of the element that has the higher thermal conductivity is higher on the one end portion side than on the other end portion side, as in the above embodiments.

In the above embodiments, in the first adhesion layer 131 and the second adhesion layer 220, the Au composition ratio in the vicinity of the Y-axis positive side is set to be not higher than 80%, and the Au composition ratio in the vicinity of the Y-axis negative side is set to be 95%. That is, the difference between the Au composition ratios on the Y-axis positive side and the Y-axis negative side is set to be not less than 15%. However, the difference between the composition ratios of the element that has the higher thermal conductivity on the Y-axis positive side and the Y-axis negative side is not limited to not less than 15%, and may be not less than 1%. In this case as well, the thermal resistance on the Y-axis negative side becomes smaller than the thermal resistance on the Y-axis positive side. Thus, the gain spectrum of the waveguide 85 positioned on the Y-axis positive side becomes a longer wave than the gain spectrum of the waveguide 81 positioned on the Y-axis negative side. As a result, the distribution of the gain spectra in the Y-axis direction becomes close to the oscillation wavelengths determined by the configuration of the optical system 300. Therefore, decrease in the light emission efficiency at each waveguide 81 to 85 of the semiconductor laser device 2 can be suppressed.

In the above embodiments, in the first adhesion layer 131 and the second adhesion layer 220, the Au composition ratio in the vicinity of the Y-axis positive side is set to be not higher than 80% and the Au composition ratio in the vicinity of the Y-axis negative side is set to be 95%. Therefore, as seen from FIG. 9(a), the thermal conductivity in the vicinity of the Y-axis positive side is set to be not higher than about 57 W/m·K, the thermal conductivity in the vicinity of the Y-axis negative side is set to be about 250 W/m·K, and the difference between the thermal conductivities is set to be not less than about 193 W/m·K. However, in the first adhesion layer 131 and the second adhesion layer 220, the difference between the thermal conductivities on the Y-axis positive side and the Y-axis negative side is not limited to not less than 193 W/m·K, and may be not less than 10 W/m·K, which is the thermal conductivity substantially corresponding to 1% of the Sn composition ratio shown in FIG. 9(a).

In the above embodiments, the contact area between the first adhesion layer 131 and the semiconductor laser element 1, and the contact area between the second adhesion layer 220 and the semiconductor laser element 1 may be configured to be greater on the Y-axis negative side than on the Y-axis positive side. For example, the width in the X-axis direction of the first adhesion layer 131 may be changed such that the contact area between the first adhesion layer 131 and the semiconductor laser element 1 is greater on the Y-axis negative side than on the Y-axis positive side. Alternatively, when the first adhesion layer 131 is present in spots in a plan view, the density of spots where the first adhesion layer 131 is present may be changed such that the contact area between the first adhesion layer 131 and the semiconductor laser element 1 is greater on the Y-axis negative side than on the Y-axis positive side. In this case, as in the above embodiments, the thermal resistance on the Y-axis negative side can be made smaller than the thermal resistance on the Y-axis positive side.

When the first adhesion layer 131 includes a void, the volume of the void in the first adhesion layer 131 can be caused to be smaller on the Y-axis negative side than on the Y-axis positive side, for example. Similarly, when the second adhesion layer 220 includes a void, the volume of the void in the second adhesion layer 220 can be caused to be smaller on the Y-axis negative side than on the Y-axis positive side, for example. When the volume of the void on the Y-axis negative side is smaller than the volume of the void on the Y-axis positive side, the thermal resistance on the Y-axis negative side can be caused to be smaller than the thermal resistance on the Y-axis positive side, as in the above embodiments.

The semiconductor laser device 2 may be used not only in processing of products but also in other usages.

In addition to the above, various modifications can be made as appropriate to the embodiments of the present invention, without departing from the scope of the technological idea defined by the claims.

### DESCRIPTION OF THE REFERENCE CHARACTERS

1 semiconductor laser element
2 semiconductor laser device
30 light emission layer
81 to 85 waveguide
110 first base
110a protrusion part (first protrusion part, first heat insulation part)
131 first adhesion layer
141 wall part (first heat insulation part)
210 second base
210a protrusion part (second protrusion part, second heat insulation part)
220 second adhesion layer
320 diffraction grating
330 output coupler (partial reflector)
R11 to R15 region (first region)
R21 to R25 region (second region)

1. A semiconductor laser device comprising:
a semiconductor laser element including a light emission layer and a plurality of waveguides arranged in one direction; and
a first base disposed, via a first adhesion layer, on one face in a lamination direction of the semiconductor laser element, wherein
a thermal resistance of the first adhesion layer is, in an arrangement direction of the plurality of waveguides, lower on one end portion side than on another end portion side.

2. The semiconductor laser device according to claim 1, wherein
the thermal resistance of the first adhesion layer is, in the arrangement direction of the plurality of waveguides, lower from the other end portion side toward the one end portion side.

3. The semiconductor laser device according to claim 1, wherein
a composition of an element, among a plurality of elements forming the first adhesion layer, that has a higher thermal conductivity is, in the arrangement direction of the plurality of waveguides, higher on the one end portion side than on the other end portion side.

4. The semiconductor laser device according to claim 3, wherein
the element, among the plurality of elements, that has the higher thermal conductivity is gold, silver, or copper.

5. The semiconductor laser device according to claim 3, wherein
between the one end portion side and the other end portion side in the first adhesion layer, a composition difference of the element, among the plurality of elements, that has the higher thermal conductivity is not less than 1%.

6. The semiconductor laser device according to claim 1, wherein
a thermal conductivity difference between the one end portion side and the other end portion side in the first adhesion layer is not less than 10 [W/mK].

7. The semiconductor laser device according to claim 1, wherein
thermal resistances of a plurality of first regions of the first adhesion layer that respectively correspond to the plurality of waveguides are, in the arrangement direction of the plurality of waveguides, lower stepwise from the other end portion side toward the one end portion side.

8. The semiconductor laser device according to claim 7, wherein
a first heat insulation part configured to block heat to be conducted in the first adhesion layer is provided between the first regions, of the first adhesion layer, that are adjacent to each other.

9. The semiconductor laser device according to claim 8, wherein
the first heat insulation part is formed by a first protrusion part provided to the first base.

10. The semiconductor laser device according to claim 1, wherein
a contact area of the first adhesion layer with the semiconductor laser element is greater on the one end portion side than on the other end portion side.

11. The semiconductor laser device according to claim 10, wherein
when the first adhesion layer includes a void, a volume of the void in the first adhesion layer is smaller on the one end portion side than on the other end portion side.

12. The semiconductor laser device according to claim 1, wherein
the semiconductor laser element is mounted in a junction down manner in the semiconductor laser device via the first base.

13. The semiconductor laser device according to claim 1, comprising
a second base disposed, via a second adhesion layer, on a face, of the semiconductor laser element, that is on a side opposite to the one face.

14. The semiconductor laser device according to claim 13, wherein
a thermal resistance of the second adhesion layer is, in the arrangement direction of the plurality of waveguides, lower on the one end portion side than on the other end portion side.

15. The semiconductor laser device according to claim 14, wherein
the thermal resistance of the second adhesion layer is, in the arrangement direction of the plurality of waveguides, lower from the other end portion side toward the one end portion side.

16. The semiconductor laser device according to claim 14, wherein
a composition of an element, among a plurality of elements forming the second adhesion layer, that has a higher thermal conductivity is, in the arrangement direction of the plurality of waveguides, higher on the one end portion side than on the other end portion side.

17. The semiconductor laser device according to claim 16, wherein
the element, among the plurality of elements, that has the higher thermal conductivity is gold, silver, or copper.

18. The semiconductor laser device according to claim 16, wherein
between the one end portion side and the other end portion side in the second adhesion layer, a composition difference of the element, among the plurality of elements, that has the higher thermal conductivity is not less than 1%.

19. The semiconductor laser device according to claim 14, wherein
a thermal conductivity difference between the one end portion side and the other end portion side in the second adhesion layer is not less than 10 [W/mK].

20. The semiconductor laser device according to claim 14, wherein
thermal resistances of a plurality of second regions of the second adhesion layer that respectively correspond to the plurality of waveguides are, in the arrangement direction of the plurality of waveguides, lower stepwise from the other end portion side toward the one end portion side.

21. The semiconductor laser device according to claim 20, wherein
a second heat insulation part configured to block heat to be conducted in the second adhesion layer is provided between the second regions, of the second adhesion layer, that are adjacent to each other.

22. The semiconductor laser device according to claim 21, wherein
the second heat insulation part is formed by a second protrusion part provided to the second base.

23. The semiconductor laser device according to claim 14, wherein
a contact area of the second adhesion layer with the semiconductor laser element is greater on the one end portion side than on the other end portion side.

24. The semiconductor laser device according to claim 23, wherein
when the second adhesion layer includes a void, a volume of the void in the second adhesion layer is smaller on the one end portion side than on the other end portion side.

25. An external resonance-type laser device comprising:
the semiconductor laser device according to claim 1;
a diffraction grating; and
a partial reflector,
the diffraction grating including diffraction grooves extending in a direction that is parallel to a direction perpendicular to the arrangement direction of the plurality of waveguides, the diffraction grating being configured to align optical axes of a plurality of laser beams emitted in accordance with the plurality of waveguides from the semiconductor laser device,
the partial reflector being configured to reflect and guide to the diffraction grating a part of the plurality of laser beams of which the optical axes have been caused to overlap with each other by the diffraction grating.
